(19) United States
(12) Patent Application Publication
(10) Pub. No.: US 2023/0249976 A1
(43) Pub. Date: Aug. 10, 2023

(54) LOW TEMPERATURE SYNTHESIS, GROWTH AND DOPING METHODS AND RESULTING MATERIALS

(71) Applicant: Jerome Cuomo, Cary, NC (US)

(72) Inventor: Jerome Cuomo, Cary, NC (US)

(21) Appl. No.: 18/085,641

(22) Filed: Dec. 21, 2022

Related U.S. Application Data
(60) Provisional application No. 63/293,482, filed on Dec. 23, 2021.

(51) Int. Cl. C01B 32/26; C01B 3/00; C01F 7/021; C01G 15/00; C01G 9/02; C30B 29/04; C30B 1/10; C30B 7/12

(52) U.S. Cl. CPC C01B 32/26; C01B 3/0026; C01F 7/021; C01G 9/02; C01G 15/00; C30B 1/10; C30B 7/12; C30B 29/04; C01P 2002/54; C01P 2002/82; C01P 2002/85; C01P 2004/02; C01P 2004/03; C01P 2004/04

(57) ABSTRACT

Low temperature synthesis, growth and doping methods and resulting materials are disclosed. According to an aspect, a method for material transformation includes providing a target material comprising carbon and/or hydrocarbon. The method also includes placing the target material within a fluid comprising a hydrogen source. Further, the method includes applying energy to the target material such that at least some of the target material is transformed to the same material with new beneficial bonding configuration.

### CROSS REFERENCE TO RELATED APPLICATION

This application claims priority to U.S. Provisional Pat. Application No. 63/293,482, filed Dec. 23, 2021, and titled LOW TEMPERATURE SYNTHESIS, GROWTH AND DOPING METHODS AND RESULTING MATERIALS, the content of which is incorporated herein by reference in its entirety.

### TECHNICAL FIELD

The presently disclosed subject matter relates generally to transformation of materials. More particularly, the presently disclosed subject matter relates to low temperature synthesis, growth and doping methods and resulting materials.

### BACKGROUND

Currently and in the past, diamond products, such as grit and powder ranging in size from micron to nanometers, have come from natural and laboratory made sources. Such processes to produce these products have been under high temperature and pressure, both natural and artificial. Reducing the efforts and costs to make such products is desirable.

With carbon’s bonding flexibility, many polymorphic possibilities exist. Some recently discovered carbon types, such as graphene and nanotubes, have been very useful in a wide variety of applications. Most of the processes to produce these useful materials are produced under equilibrium conditions where limits are set by temperature and pressure for example the limitations for doping contractions. In addition, exploring the production of molecules such as in Sp, Sp2 and even Sp3 bonding coordination of carbon, low temperature and new catalytic reaction paths are constantly being studied and practiced, and there has been a long standing need to improve such processes.

In view of the foregoing, there is a continuing need to improve the techniques for synthesis of materials, such as carbon based materials, that are non-thermal and non-pressure dependent.

### BRIEF DESCRIPTION OF THE DRAWINGS

Having thus described the presently disclosed subject matter in general terms, reference will now be made to the accompanying Drawings, which are not necessarily drawn to scale, and wherein:

FIG. 1 is a flow diagram of an example method of material transformation in accordance with embodiments of the present disclosure;

FIG. 2 is a flow diagram of another example method for material transformation in accordance with embodiments of the present disclosure;

FIG. 3 is a flow diagram of another example method for material transformation in accordance with embodiments of the present disclosure;

FIG. 4 is a scanning electron microscope (SEM) image showing the resulting target material after the exposure to the Mercury lamps;

FIG. 5 is an SEM image shows an indication of epitaxial growth due the alignment of the separated crystals indicating the influence of the sapphire substrate on the growth;

FIG. 6 is a graph of a Raman spectra showing absorption lines associated with the diamond structure;

FIG. 7 is another graph showing large crystals and small crystals have the same structure;

FIG. 8 is an SEM image of crystalline clusters growing together, which is characteristic of migration and diffusion of molecules and atoms of the synthesis and growth process;

FIG. 9 is an SEM image showing an electron beam drilled crystal showing a hexagonal hole as well as the layered homoepitaxial growth and heteroepitaxial to the substrate;

FIG. 10 is a graph of EDS analysis showing that the crystals are carbon, the Au and Pd are from a sputtered layer to prevent surface charging;

FIG. 11 is a transmission electron microscope (TEM) image showing the atomic arrangement of carbon (diamond) grown from petroleum jelly, which is a hydrocarbon transformed into single crystals at near or at room temperature with UV light as an energetic source of instant energy and it is believed that atomic hydrogen is mediating the transformation;

FIG. 12 is an SEM image showing experimental results with the atomic arrangement of carbon (diamond) grown from petroleum jelly;

FIG. 13 is an image captured showing the non-extruded Nylon sample on the left practically all the material is gone;

FIG. 14 is an image at 1000X magnification of the extruded Nylon and after heating at about 650° C.;

FIG. 15 is an image of the resulting product, which shows the resulting solid yellow crystals;

FIG. 16 is an image showing the resulting product with crystals being yellowish in color and some having a bluish coloration. Particularly, this image is nitrogen doped Sp3 carbon (i.e., diamond) at 1000X magnification;

FIG. 17 is a graph of Raman spectra of the crystal product of N-doped Sp3 carbon 10′s of micron;

FIG. 18 is an image of 1000X magnification of N-doped Sp3 carbon from Melamine mixed with nanodiamond powder of 6 to 10 nm treated with UV light;

FIG. 19 is an image of resulting N-doped diamond;

FIG. 20 is a graph of Raman spectra showing the sharp absorption distinctly different from nano diamond powder and like single crystal diamond;

FIG. 21 is a graph (along with description) of Raman spectra of the resulting product of the experiment;

FIG. 22 is an image of the resulting product along with description;

FIG. 23 is an image showing blue crystals micrometers in size with the color of blue diamonds;

FIG. 24 is an image at 100X magnification of the blue transparent fibers that scratch sapphire;

FIG. 25 is an image at 100X magnification of thiophene only with UV light;

FIG. 26 is an image at 1000X magnification of the crystalline product where thiophene was used as the target material and the process was applied with UV light;

FIG. 27 is an image at 200X magnification after 3 to 5 second treatment of a carbon powder mud (water/alcohol) with a Dremel tool at 38,000 RPM;

FIG. 28 is an image at 500X magnification showing transparent crystals of carbon after 3 to 5 seconds treatment with a Dremel tool at ∼38,000 RPM;

FIG. 29 is an image at 200X magnification showing that the crystals are transparent and relatively uniform in size by the shearing action of the Dremel tool;

FIG. 30 is an image of 1000X magnification showing transparent crystals in seconds from petroleum jelly hydrocarbon with ethanol and water as starting materials;

FIG. 31 is an image of 500X magnification showing scratching of sapphire as an indicator of a material transformation to Sp3 carbon;

FIG. 32 is an image of 1000X magnification of transparent material produced from petroleum jelly with a Dremel tool at 38,000 rpm in seconds at room temperature;

FIG. 33 is an iamge of 1000X magnification of extreme/extrusion E2 of petroleum jelly;

FIG. 34 is an iamge of 1000X magnification of extreme/extrusion of pure carbon powder transformed in about 15 seconds with a drill at 1500 RPM;

FIG. 35 is an image showing signs of extrusion/shearing with elongated growth;

FIG. 36 is an image at 500X magnification showing the crystal growth from nanodiamonds to crystals hundreds of microns in size;

FIG. 37 is an image of 500X magnification showing nano size detonation diamonds grown to micron size crystals and doped with lithium producing blue colored crystals;

FIG. 38 is an image showing resulting product of an experiment using lithium salt Li₂CO₃;

FIG. 39 is an image of 500X magnification of resulting product;

FIG. 40 is an image of 500X magnification of the resulting product from extrusion of Nylon plus water and ethyl alcohol and treated with a Dremel tool at 38,000 RPM;

FIG. 41 is an image showing resulting residues treated with hot conc. HCl and further with hot concentrated H₂SO₄ with Conc, HF;

FIG. 42 is an image showing that the resulting particles are transparent and scratch sapphire;

FIG. 43 is an image showing residue from the treated PET container scratched sapphire;

FIG. 44 illustrates an image with 500X magnification showing the yellow-colored crystals anticipated for nitrogen doped Sp3 carbon that scratches sapphire and stable at ~700° C.;

FIG. 45 is an image of 500X magnification of crystal produced by atmospheric plasma treatment of vapors of n-heptane and carbon disulfide;

FIG. 46 is an image of 500X magnification showing resulting crystals;

FIG. 47 is an image of 500X magnification with transmitted light;

FIG. 48 is an image of 500X magnification showing a result of the product material scratching sapphire;

FIG. 49 is an image of 500X magnification of transparent crystals produced by the treating diesel-like oil with a Dremel tool for about 15 seconds and after heating in air for about 30 minutes;

FIG. 50 shows a graph of Raman spectra of the product;

FIG. 51 shows a graph of Raman spectra of the product;

FIG. 52 is an image showing containers with resulting samples that demonstrate the areas that have interacted with water;

FIG. 53 is an image showing on the far left the Niobium sheet dark and light area that has a corresponding image on the litmus paper. The white area is a result of light sanding of the surface;

FIG. 54 is an image of 1000X magnification of Cr doped A1203 (ruby);

FIG. 55 is an image of 1000X magnification of Cr doped Al₂O₃ powder that grew as well as incorporated the Cr into the lattice producing ruby;

FIG. 56 is an image of titanium doped Al₂O₃ at room temperature (Ti-Sapphire);

FIG. 57 is an image at 200X magnification of the resulting product;

FIG. 58 is an image of 1000X magnification of a resulting product that demonstrates atomic hydrogen tunneling;

FIG. 59 is a graph depicting Raman spectra with polyethylene glycol (PEG) / ethyl alcohol (EtOH) / hammer shocked at liquid nitrogen temperature -198° C.;

FIG. 60 is another a graph depicting Raman spectra with nickel loaded with hydrogen by electrolysis with dodecane C₁₂ and ethanol cooled to liquid nitrogen and hit with an air driven hammer for about 10 seconds;

FIG. 61 is an image showing that within seconds of contact with the litmus paper it turned BLUE indicating the water became basic;

FIG. 62 is image showing on the far left the Niobium sheet dark and light area that has a corresponding image on the litmus paper; and

FIG. 63 is an image of 500X magnification of resulting product that shows the crystals that grew on the surface with slight warming of the wafer.

### SUMMARY

The presently disclosed subject matter relates to low temperature synthesis, growth and doping methods and resulting materials. According to an aspect, a method for material transformation includes providing a target material comprising carbon organic hydrocarbon and/or inorganic hydrocarbon. The method also includes placing the target material within a fluid comprising a hydrogen source. Further, the method includes applying energy to the target material such that at least some of the target material is transformed to the same material with a different bonding configuration.

According to another aspect, a method of material transformation includes providing a target material comprising a metal oxide. The method also includes placing the target material within a fluid comprising a hydrogen source. Further, the method includes applying energy to the target material such that at least some of the target material is transformed to the same material with different bonding configurations containing a dopant.

According to another aspect, a method of material transformation includes effusing an active ingredient from a reserve-reservoir of atomic hydrogen from within materials that absorb hydrogen gas. Further, the method includes migrating of target materials to a surface of a reserve-reservoir of atomic hydrogen where the material reacts and transforms to a different configuration

### DETAILED DESCRIPTION

The following detailed description is made with reference to the figures. Exemplary embodiments are described to illustrate the disclosure, not to limit its scope, which is defined by the claims. Those of ordinary skill in the art will recognize a number of equivalent variations in the description that follows.

Articles “a” and “an” are used herein to refer to one or to more than one (i.e. at least one) of the grammatical object of the article. By way of example, “an element” means at least one element and can include more than one element.

“About” is used to provide flexibility to a numerical endpoint by providing that a given value may be “slightly above” or “slightly below” the endpoint without affecting the desired result.

The use herein of the terms “including,” “comprising,” or “having,” and variations thereof is meant to encompass the elements listed thereafter and equivalents thereof as well as additional elements. Embodiments recited as “including,” “comprising,” or “having” certain elements are also contemplated as “consisting essentially of” and “consisting” of those certain elements.

Recitation of ranges of values herein are merely intended to serve as a shorthand method of referring individually to each separate value falling within the range, unless otherwise indicated herein, and each separate value is incorporated into the specification as if it were individually recited herein. For example, if a range is stated as between 1% - 50%, it is intended that values such as between 2% - 40%, 10% - 30%, or 1% - 3%, etc. are expressly enumerated in this specification. These are only examples of what is specifically intended, and all possible combinations of numerical values between and including the lowest value and the highest value enumerated are to be considered to be expressly stated in this disclosure.

Unless otherwise defined, all technical terms used herein have the same meaning as commonly understood by one of ordinary skill in the art to which this disclosure belongs.

In accordance with embodiments, the presently disclosed subject matter involves treating target materials at low temperature (e.g., liquid nitrogen temperature, room temperature, near room temperature, and/or the like) combined with at least one or more sources of high energy (e.g., UltraViolet (UV) light, electrolysis, shearing, shock, shock and shear, (extrusion/ultrasonics), plasma, high electric fields, atomic hydrogen, and/or the like) to transform and/or modify the structure of the target in conjunction with a mediating agent that is added to or extracted from the target. The delivery or application of this instantaneous energy or near instantaneous energy coupled with a mediating agent can transforms the target to the desirable product. I.e. this application of energy to the target material can transform all or at least some of the target material to the same material with a different bonding configuration. For example, the presently disclosed subject matter provides for transformation and crystal growth of carbons, such as Sp, Sp2, Sp3, to Sp3 carbon, diamond, and/or diamond-like structures. With the formation of the products under metastable processing conditions, there is evidence of the formation of hexagonal crystals with the indication of a polymorphic form of Sp³ carbon that can have improved properties over the cubic form of diamond. In addition, these target materials are also shown to be grown co-opting dopants that produce useful and valued products derived from the target materials. During experiments as described herein for example, it was found that in generation of the transformation, the product formation takes place within the unreacted target material continuedly. The products that are formed in some and, in particular, the emulsion forming processes, of the instant energy applications, is in contact with the fluids that can attach and functionalize the very active surface of the formed product. In experiments, this was discovered to be favorable for utilitarian applications such as for machining articles of high hardness can be machined (e.g., drilled) with tools of lesser hardness where the transformation takes place at the interface of the tool and the target material with the activating agent. For example, a steel drill can be able to drill into alumina with hardness differences from 6.5 steel to 9 for alumina from this it can be foreseen to use a hydrocarbon such as pertroleum jelly (e.g., VASELINE® brand petroleum jelly available from Conopco, Inc.), with the added mediator and the energy provide by drilling can produce Sp3 hard material continuedly during the processing. It should be appreciated to those of skill in the relevant art from the forgoing arguments that other hydrocarbons (e.g., carbon organic hydrocarbon and/or inorganic hydrocarbon) and various conditions described with respect to embodiments disclosed herein can produce similar results.

Further still, it has been found in experimental results that under intense shear applications, the target material can be transformed and cold welded to a substrate and deposit cohesively with the substrate with a coating of the product Sp³ carbon (diamond). As such low coefficients of friction can be added to high frictional surfaces. It is anticipated that as higher and higher sliding and circular rotating devices from a standard home drill at speeds of 1800 rotation per minute (RPM), to higher RPM (e.g., rotational rates such as 38,000 RPM achieved by DREMEL® brand drill tools available from Robert Bosch Tool Corporation), and to dental drills with rotational speeds of 400,000 RPM that can torque down to 200,000 RPM. It is anticipated that the formation of transformed material to be enhanced. It is still further anticipated that surfaces such as gun-rails and the like where the performance and wearing of the surface can benefit from an in situ production of a hard low coefficient of friction of a diamond or diamond-like surface.

The disclosed subject also relates to other materials such as Aluminum Oxide (AlO) that will grow and co-opt dopants to convert to gemstones, such as Ruby, as well as Ti-sapphire as with some or all the same energy sources and mediating agents.

The disclosed target materials are from the class of carbons, hydrocarbons, organic and inorganic minerals such as: oils (olive, mineral oil, diesel oil (natural or synthetic), canola oil, and-the-like), greases (Vaseline, petroleum jelly, vitamin E, and-the-like), polymers (nylon, hydrocarbon liquids (hexane and the like) and solids (polyethylene, polyethylene glycol, ethylene glycol, naphthalene, adamantane, from the class of alkanes as well as aromatic compounds and-the-like in various forms as in emulsions with water and or alcohols. Other example target materials from another class of materials include, but are not limited to, oxides of Aluminum, Gallium, Zinc, Indium, Geranium and-the-like, and the doping therein. The application to the target in principle and/or in part, follow the treatments of the instant energy process for the carbon materials. In these materials, the atoms and molecules can be extruded and self-aligned in accordance with the disclosed subject matter.

Organic materials includes, but are not limited to, plastic bags, water bottles, plastic wrapping such as food plastic wrap (e.g., “Cling Wrap” food plastic wrap available from The Glad Products Company), PET containers, living organic materials (e.g., spider webs), mushroom tendrils, carotene from fingernails and hair, and paper from a wasp nest. In these materials, the atoms and molecules can be extruded, aligned and self-aligned respond to the treatment for the transformation and crystal growth to Sp³ carbon that survives 750° C. heating in air and scratches sapphire. These products are formed at about room temperature and at liquid nitrogen temperature which where the rates of growth are non-Arrhenius and have quantum tunneling characteristics.

During this work and experiments, it was discovered that diamonds were found in extruded materials of carbon and hydrocarbons as a result of methods conducted in accordance with the present disclosure. It was discovered that diamond resulted from methods disclosed herein that were applied to pencil lead, rubber tires (the controlled burning of rubber tires), rubber bands, and rubber casters from office chairs. These materials were produced under extreme extrusion conditions of several tons of pressure, through fine nozzles or rollers.

Targets disclosed herein were treated with the instant energy process at least one or more together with the mediator material such as water and or ethyl alcohol. The target material was observed to transform to Sp³ transparent crystals that survives 750° C. from minutes to tens of hours in an air furnace.

The product coming from only a carbon source, scratches sapphire, was examined with SEM/EDX showing the crystals are carbon with some carried to Raman analysis showing Raman spectra like diamond or nano-diamond, in some cases high resolution TEM was performed showing single crystal structure as well as indications of the hexagonal diamond form that is reported to be many times harder that the cubic form of diamond.

In accordance with embodiments, energetic processes are disclosed that transform, convert, and grow target materials. These act under different fluences and access to the targets. Example processes that apply instant energy to the target include, but are not limited to, application of energy by tools that apply shear and extreme shear to the target materials. Example tools include high-rotational speed drilling tools, dental drills, ball milling, or other tools that apply ultrasonic stress alone or in combination with other suitable tools. All these processes are of sufficient energy to release hydrogen in its atomic form. This work shows that organics under such molecular bond stress in the presence of a mediating agent can transform rapidly and with such speed that challenges the reaction rate governed by Arrhenius equations, and can react as non-Arrhenius reaction rates even at liquid nitrogen tempertures. Such evidence strongly suggests a quantrum tunneling mechanism.

Various materials can absorb hydrogen gas and diffuse through the lattice structure in atomic form, effuse and reemerge in the atomic form on the surface. The presently disclosed subject matter uses this effect to continuously react and transform target materials from liquid nitrogen to room temperature and beyond. Herein is demonstrated by experiments with classic observations that clearly show non-Arrhenius quantum behavior where extremely rapid growth rates are observed.

Demonstrated herein are examples of the transformation of Sp carbon to Sp³ carbon through the single crystal growth on sapphire with petroleum jelly as representative of the hydrocarbon class of materials. This result opens associated results of this research that at room temperature and near room temperature, and at liquid nitrogen temperature, doping of the Sp³ carbon are realized, co-opting this result. With these results, epitaxial growth of doped diamond on sapphire and other suitable substrates (Silicon Carbide, Aluminum Nitride, Gallium Nitride, as well as diamond and the like) can demonstrate the same results will be recognized by those of skill in the art.

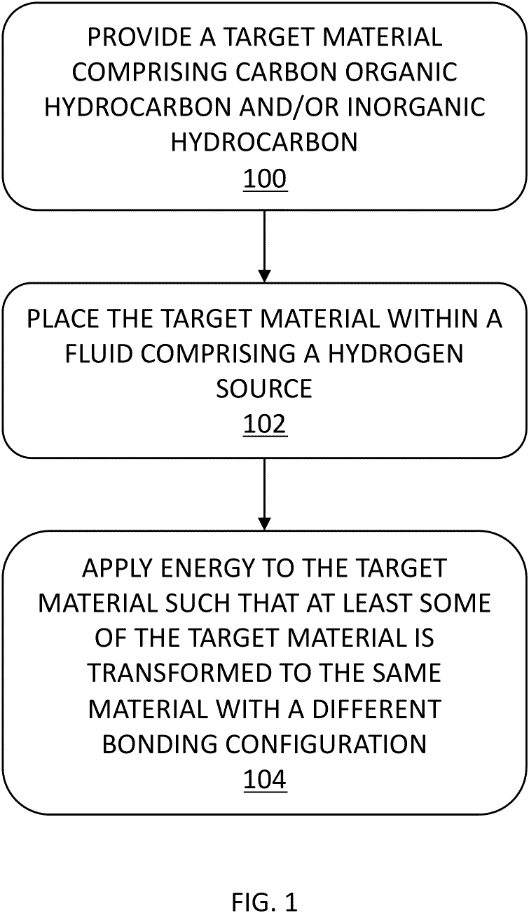

FIG. 1 illustrates a flow diagram of an example method of material transformation in accordance with embodiments of the present disclosure. In an example, the steps of the method can be implemented at between about -198° C. and about and above 400° C. Further, the the target material can be placed in contact with water and/or alcohol vapor, liquid or as a frozen solid and/or a surface to which atomic hydrogen has diffused to.

Referring to FIG. 1, the method includes providing 100 a target material comprising carbon organic hydrocarbon and/or inorganic hydrocarbon. Example target materials include, but are not limited to, inorganic liquid, solid hydrocarbons, olive oil, mineral oil, diesel oil, canola oil, greases, polymers, and/or the like. In yet other examples, target materials include, but are not limited to, Aluminum, Gallium, Zinc, Indium, Geranium, and/or the like. In other example, the target material can include Sp carbon, Sp2 carbon, and/or Sp3 carbon. Example fluid includes, but is not limited to, water, alcohol, atomic hydrogen, the like, or combinations thereof.

The method of FIG. 1 includes placing 102 the target material within a fluid comprising a hydrogen source. Continuing the aforementioned example, energy can be applied to the target material for a predetermined period of time such that energy is provided for supporting the different bond transformation. The predetermined period of time can be one of microseconds, seconds, days in accordance with an amount of energy applied to the target material that transforms the target material that is consistent with the energy source and mode and form of the energy delivered consistent with each form of energy consistent with its nature. Examples of applying energy to the target material include, but are not limited to, applying to the target material ultraviolet (UV) light, mechanical force, shear force, compressive force through extrusion, and or ultrasonics, electrolysis, atmospheric plasma, high electrical fields, hydrogen ionic and/or atomic to create and deliver energetic particles to mediate structural change with respect to the energy source and the fluence from that source. Image of the applied energy can be instant, local to the target material such that particle release mediates the transformation of the target material to a different stable form at ambient and near ambient conditions without change in an overall thermal energy change to the target material. In another example, ultraviolet photon energy can be applied to the target material that is one of between about 200 newton nanometers (nm) to about 400 nm, or between about 10 nm and about 200 nm in vacuum or inert gas conditions. The atoms and molecules of the target material can experience mechanical forces that weaken and scissor bond, mediate the transformation of the target material to a different stable form, from liquid nitrogen to ambient and near ambient conditions without change in an overall thermal energy of the target material. The application of force can be, for example, applying force the target material through a die or through rollers; applying mechanical shock and/or shear forces to the target material; and/or applying contact with hydrogen in its activated form ion or atomic. The target material can be grown onto a surface other than the target. The target material may be grown unto itself. In an example, the target material may contain the dopant as part of the hydrocarbon. The target hydrocarbon is mixed with a material containing the dopant. The dopant concentrations may exceed equilibrium conditions. In an example, synthesis of the target material is grown on a substrate, heteroepitaxial, or on a substructure in kind, homoepitaxially. In another example, growth may take place at a temperature between about -193 centigrade and about 400 degrees centigrade. In another eample, growth takes place on the surface of UV transparent material, wherein the energy is delivered through an UV transparent material to the interface of the target material and continues through the product to grow. In an example, target material is a petroleum jelly and water/alcohol mixture compressed between wafers with at least one being single crystal sapphire wafers and exposed to UV light.

In embodiments, the method can include doping the target material. For example, the target material can be doped with nitrogen, boron, lithium, sulfur, phosphor(o)us, silicon, and/or the like.

The method of FIG. 1 includes applying 104 energy to the target material such that at least some of the target material is transformed to the same material with a different bonding configuration. Continuing the aforementioned example, the target material can be transformed into a solid crystalline or amorphous and/or material mixture thereof. Example energies that can be applied to the target material include, but are not limited to, UV light, electrolysis, shearing, (extrusion/ultrasonics), plasma, high electric fields, and the like. The target material with the different bonding configuration can be heat treated at between about 500 centigrade and about 750 centigrade in air. For example, energy can be applied to the target material with the Sp carbon, the Sp2 carbon, and/or the Sp3 carbon such that the Sp carbon, the Sp2 carbon, and/or the Sp3 carbon transforms to Sp3 bonding configurations for synthesis and/or growth. The target material may be all or in part single crystal. In an example, the product is single crystal, epitaxial, or doped.

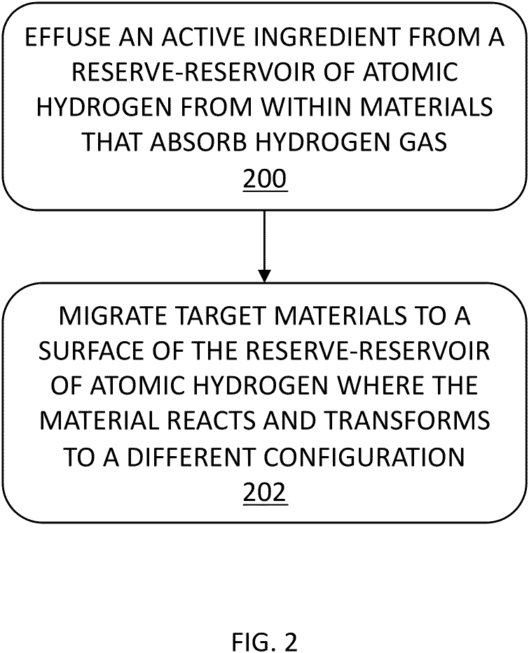

FIG. 2 illustrates a flow diagram of another example method for material transformation in accordance with embodiments of the present disclosure. Referring to FIG. 2, the method includes effuse 200 an active ingredient from a reserve-reservoir of atomic hydrogen from within materials that absorb hydrogen gas. For example, the reserve-reservoir of atomic hydrogen is from materials including one of Pd, Nb Au, Ag Zr, Ti, Cu, combinations thereof, and alloys thereof.

The method of FIG. 2 includes migrating 202 of target materials to a surface of the reserve-reservoir of atomic hydrogen where the material reacts and transforms to a different configuration. Continuing the aforementioned example, the product can be single crystal, epitaxial, or doped.

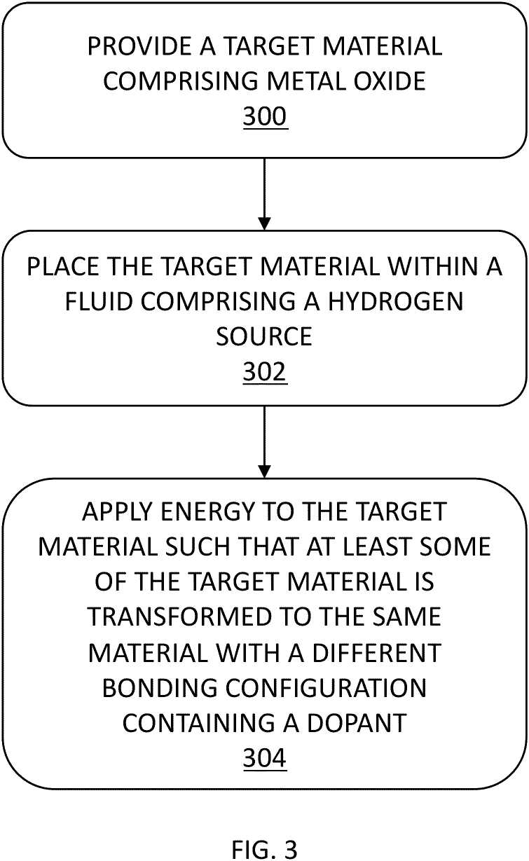

FIG. 3 illustrates a flow diagram of another example method for material transformation in accordance with embodiments of the present disclosure. Referring to FIG. 3, the method includes providing 300 a target material comprising metal oxide. Example metal oxides can include Aluminum Oxide and Gallium Oxide, Zinc Oxide, and/or the like. The method of FIG. 3 can also include placing 302 the target material within a fluid comprising a hydrogen source. Further, the method of FIG. 3 can include applying 304 energy to the target material such that at least some of the target material is transformed to the same material with a different bonding configuration containing a dopant. For example, a dopant concentration of the material with different bonding configurations can be between 0.03% to 0.05% Chromium with lower 0.01% to 0.2% transforms to a dope sapphire.

Experiments were conducted in accordance with embodiments disclosed herein. Descriptions of the experiments follow:

### Experimental Example 1

Ultraviolet light synthesis and crystal growth were demonstrated in an experiment. The sample of this experiment was prepare with petroleum jelly mixed with water and/or alcohol from 0.01 to 5% or more. This was sandwiched between two c-axis sapphire wafers and exposed to UV light from three mercury lamps for about 20 hours. It is noted that sapphire is transparent to UV light in the 184 to 1014 nm wavelength range - spectral Hg.

The high energy can be sufficient to energize the molecular bonds and allow bond rearrangement to take place without any significant thermal impact to the product. It is believed that the rearrangement is mediated by atomic hydrogen possibly through non-Arrhenius reaction rates potentially demonstrating quantum tunneling processes.

In this example, several aspects of present disclosure were demonstrated. Particularly, it can be observed that hydrocarbon petroleum jelly mixed with a mediating agent water and/or alcohol energized with UV light for short or extended times transforms to a stable Sp3 carbon (diamond). This occurs at or about room temperature and atmospheric pressure. This stabilizies when heated to about 750 degress C for several hours. The product scratches sapphire, thus supporting a finding that the product is Sp3 carbon. If the target material is only of carbon, hydrogen, or some combination and it scratches sapphire, then the conclusion should be that the result is diamond. In addition, the synthesis and growth of the sample in this example are single crystal and demonstrates heteroepitaxial growth as related to the substrate and homoepitaxial growth as it continues to grow on itself.

What is further shown in this example is that the Raman Spectra conforms to that of Sp3 carbon. Continued analysis show the material to be carbon by SEM/EDX and TEM analysis shows the single crystal structure at an atomic level, also showing the rare hexagonal form and potentially other polymorphs of carbon. This first example is now amplified by the following examples that incorporate various targets, energy sources, conditions particular to the process doping incorporation into the structure.

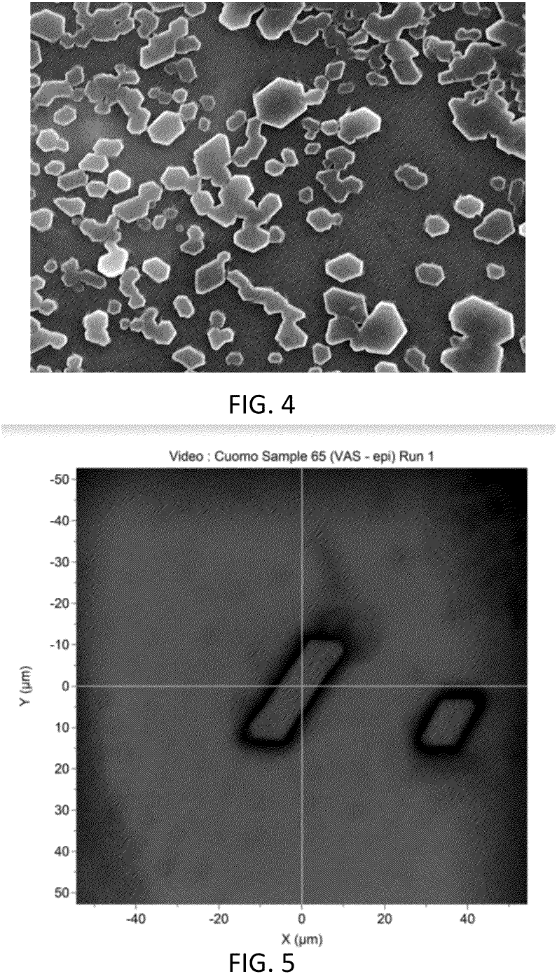

In this experiment, a target material (or sample) is exposed to Mercury lamps wrapped in highly reflective foil made of Aluminum. FIG. 4 is a scanning electron microscope (SEM) image showing the resulting target material after the exposure to the Mercury lamps.

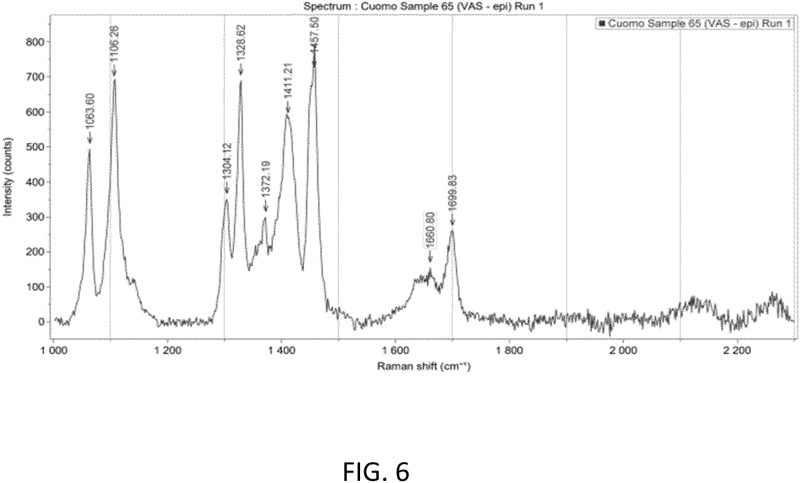

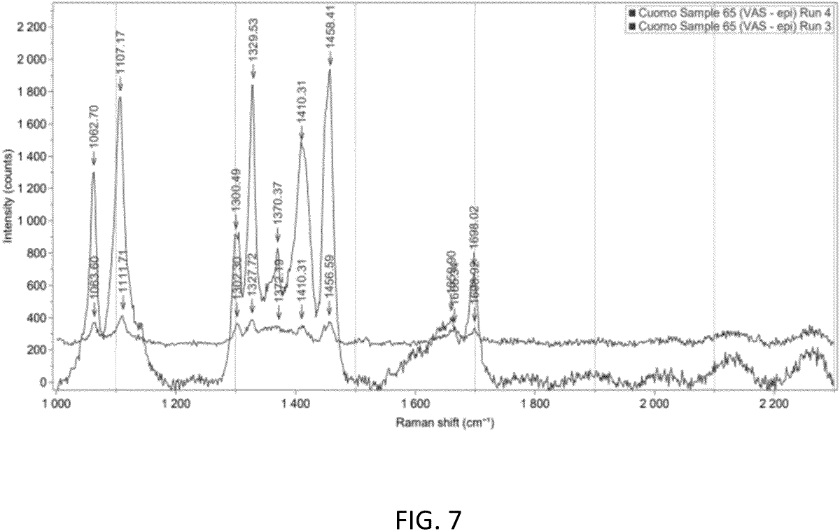

FIG. 5 is an SEM image shows an indication of epitaxial growth due the alignment of the separated crystals indicating the influence of the sapphire substrate on the growth. FIG. 6 is a graph of a Raman spectra showing absorption lines associated with the diamond structure. FIG. 7 is another graph showing large crystals and small crystals have the same structure.

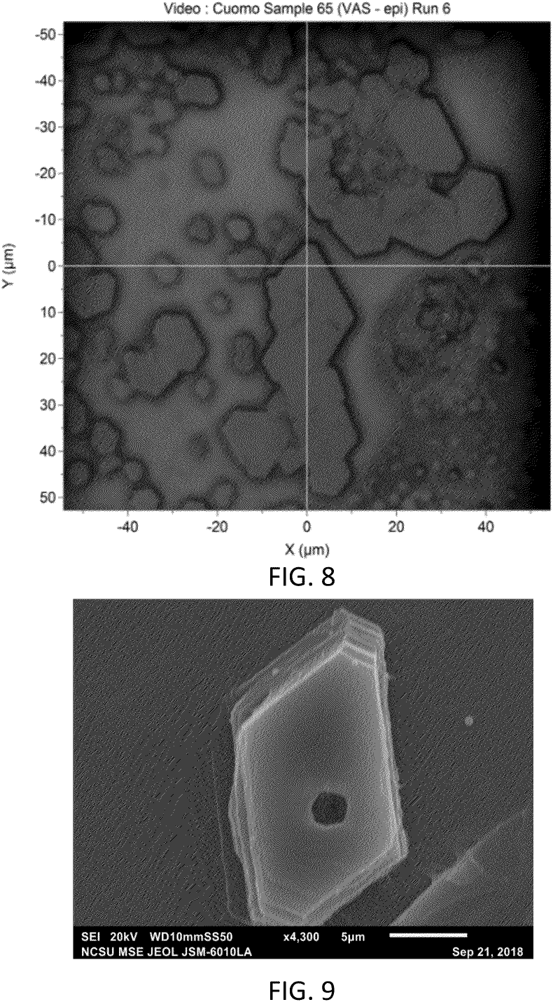

FIG. 8 is an SEM image of crystalline clusters growing together, which is characteristic of migration and diffusion of molecules and atoms of the synthesis and growth process. The attachment of the growing crystals and some orientation directional changing to the growth are influenced by defects associated with the interface of the crystal, that which acts as the substrate to the growth. This surprising result of growth at and near room temperature has been repeated.

FIG. 9 is an SEM image showing an electron beam drilled crystal showing a hexagonal hole as well as the layered homoepitaxial growth and heteroepitaxial to the substrate.

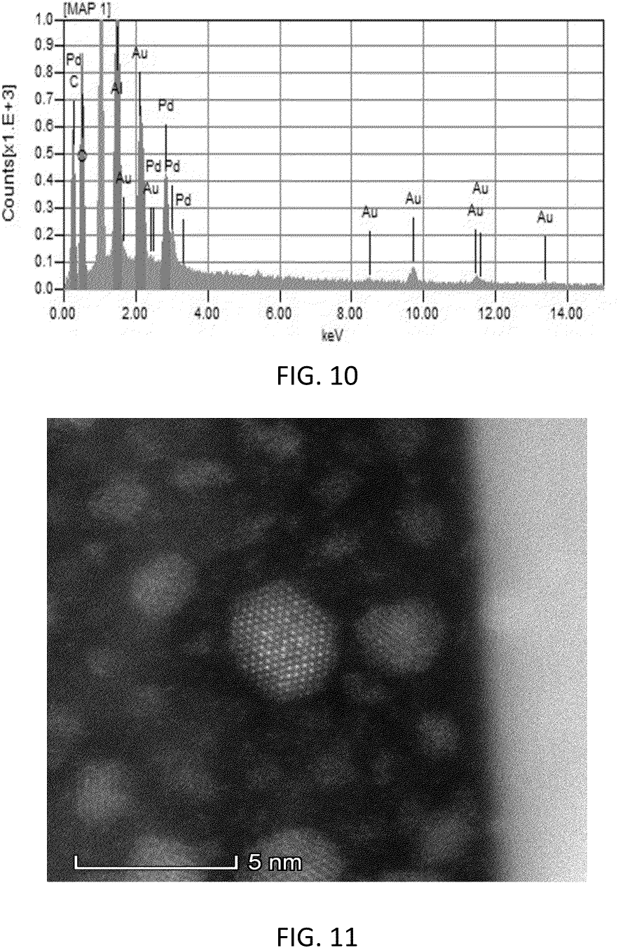

FIG. 10 is a graph of EDS analysis showing that the crystals are carbon, the Au and Pd are from a sputtered layer to prevent surface charging.

FIG. 11 is a transmission electron microscope (TEM) image showing the atomic arrangement of carbon (diamond) grown from petroleum jelly, which is a hydrocarbon transformed into single crystals at near or at room temperature with UV light as an energetic source of instant energy and it is believed that atomic hydrogen is mediating the transformation.

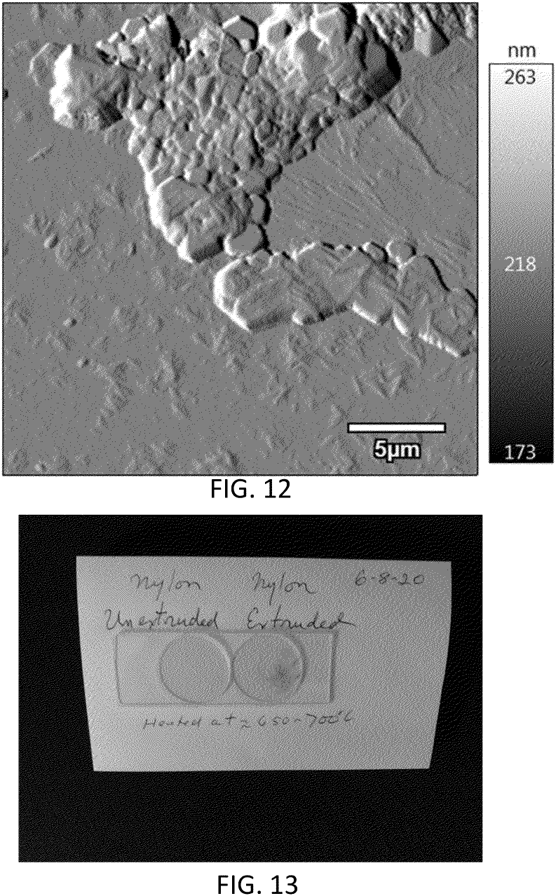

FIG. 12 is an SEM image showing experimental results with the atomic arrangement of carbon (diamond) grown from petroleum jelly.

### Experimental Example 2

In another experiment, work was conducted to examine a plethora of hydrocarbon transformations for conversion to diamond at room temperature with UV light and H₂O/ET-0H. Naphthalene with its high vapor pressure and with the thought that vapor phase conversion can be processed under ambient conditions to thereby producing nano-diamonds.

The process for this example experiment includes placing a small amount of naphthalene in a cavity made up of two fused silica boats with a few drops of water added. Subsequently, a mercury lamp was placed over the chamber and covered with aluminum foil. The sample was radiated for approximately 10 hours. These were heated to remove all the volatiles first and were subsequently heated to 650° C. for about 3 hours. Several clear transparent crystals were observed and were found to scratch sapphire. This was one step utilized to characterize the material. It is believed that the material resulting from this experiment is Sp3 diamond and of diamond-like carbon. This is because when a material that only contains carbon from a hydrocarbon source and the product that has survived 650 degress C for > 10 hours, therefore the result is an Sp3 diamond and of diamond-like carbon if it can scratch sapphire.

### Experimental Example 3

This example experiment demonstrates the effect of extreme shear through extrusion on Virgin Nylon (or any similar synthetic polymer, which may be composed of polyamides) and the extrusion of the Virgin Nylon. It is noted that Nylon is a silk-like thermoplastic, generally made from petroleum, that can be melt-processed into fibers, films, or shapes. In this experiment, chemically prepared nylon was utilized, which was non-extruded made by the polymerization of aminocaproic acid, (H₂N(CH₂)₅COOH).

The experiment includes providing the chemically-prepared Nylon. The Nylon is extruded by squeezing between two bolts and a nut. It should be appreciated that any other suitable technique for extrusion may be utilized. The product resulting from the extrusion was removed and deposited on a silicon wafer, and the non-extruded Nylon is deposited on another silicon (Si) wafer. Both wafers were heated side-by-side on a hotplate to about 550° C. and compared.

FIG. 13 is an image captured showing the non-extruded Nylon sample on the left practically all the material is gone. While on the sample on the right, the extruded Nylon shows a white crystalline residue remains on the silicon wafer. It is noted that the white crystalline residue scratches sapphire. The remaining residue is yellowish in color which is the color of nitrogen doped diamond and nitrogen is part of the composition of nylon.

FIG. 14 is an image at 1000X magnification of the extruded Nylon and after heating at about 650° C.

### Experimental Example 4

Sulfur has been reported to be incorporated into the diamond structure and act a dopant in the literature. In this experiment, the process produced a diamond structure with sulfur incorporated into the lattice such that the color of the Sp3 crystal was colored with shades of yellow to brownish yellow among others. Images captured of the resulting product of the experiment show the effect. The following data reports the current information that supports the sulfur inclusion observations.

The experiment included mixing thiophene, a sulfur containing hydrocarbon, with petroleum jelly with ethanol and/or water. This cyclic hydrocarbons with the potential dopants were treated with energetic processes such as shearing (e.g., extrusion, ultrasonics, ball milling) or radiation (UV or energetic particles). UV light was applied. As a result, yellowish crystals formed and after heating to about 750° C. The resulting product was observed to scratch sapphire. FIG. 15 is an image of the resulting product, which shows the resulting solid yellow crystals.

### Experimental Example 5

This experiment involves UV light synthesis and doping. Particularly, the experiment includes doping of Sp3 carbon with UV light as the energy source. The production of Sp3 carbon resulted from Sp, Sp2 carbon, doping and growth of diamond with Nitrogen, Lithium, Sulphur, Boron, Phosphorous and Silicon at room temperature.

The synthesis of Sp3 carbons with dopants was formed by co-mixing a compound containing the element of interest or by using a compound containing the element alone or with another hydrocarbon. The following have been used with crystals formed that showed evidence of incorporation of the intended dopant in the product. The energetic processes, so far, that demonstrate the synthesis and doping are: observation of crystallization optically, shows evidence of hi index of diffraction of light, scratches sapphire, SEM/EDX shows carbon as the principal element present, Raman spectra showing evidence of Sp3 spectra (additionally, some samples are further examined with TEM and X-Ray analysis). These observations indicate that a transformation has taken place.

### Experimental Example 6

This experiment involves synthesis and growth of nitrogen-doped Sp3 carbon. An objective of this experiment was to synthesize and dope Sp3 carbon, diamond, with nitrogen. The experiment involved: mixing nano-diamond powder, as nuclei with melamine a nitrogen containing cyclic hydrocarbon powder; spread a mixture of nanodiamond and melamine onto a substrate; confine the mixture with a liquid and vapor of water and ethyl alcohol; and expose the mixture to UV light from mercury lamps for several hours as is shown in Example Experiment 1. The results of this experiment show significant single crystal growth with nitrogen content.

Optical photographs or images of several of the products of this experimental process were captured. In each of the cases the starting materials are dotation nano-diamonds about 10 nm and with clusters that vary in size. After treatment the resulting crystals were greater than hundreds of microns. Some of the crystals are yellowish in color and some have a bluish coloration that may be due to the large concentration of nitrogen in the crystal.

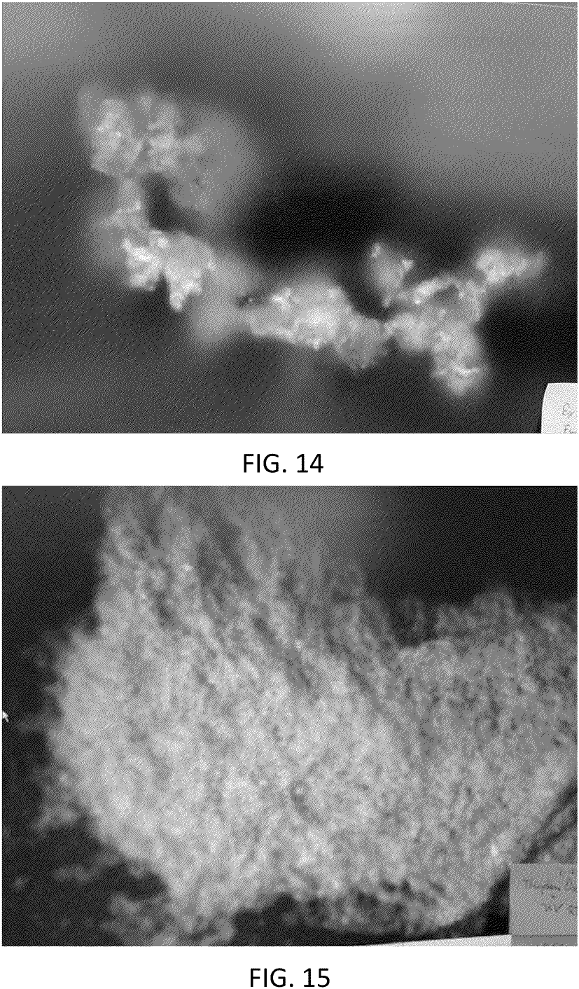

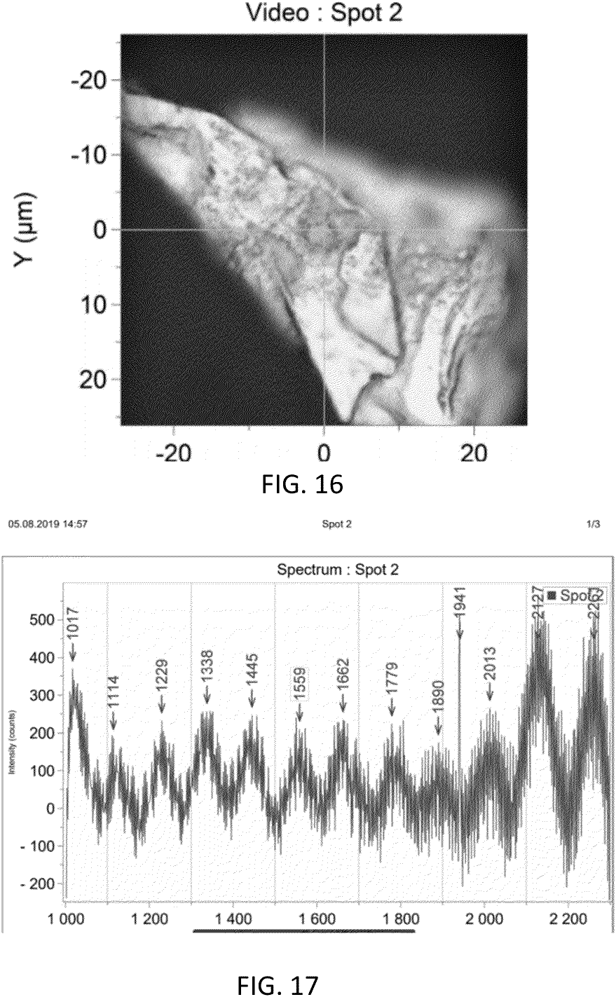

FIG. 16 is an image showing the resulting product with crystals being yellowish in color and some having a bluish coloration. Particularly, this image is nitrogen doped Sp3 carbon (i.e., diamond) at 1000X magnification.

FIG. 17 is a graph of Raman spectra of the crystal product of N-doped Sp3 carbon 10′s of micron.

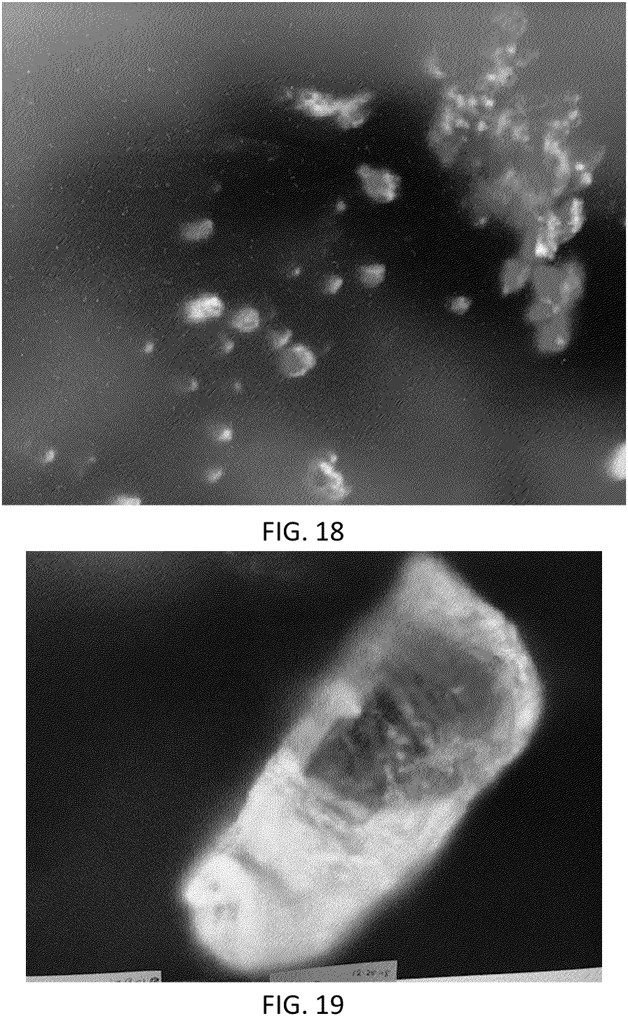

FIG. 18 is an image of 1000X magnification of N-doped Sp3 carbon from Melamine mixed with nanodiamond powder of 6 to 10 nm treated with UV light. A yellow to orange color was observed and believed to be associated with the presence of nitrogen in the lattice of Sp3 carbon.

SEM/EDX Analysis results follow

| Chemical formula | | | ms% | mol% Sigma | Net | K Ratio Line |
|---|---|---|---|---|---|---|
| C | 39.16 | 67.74 | 0.15 | 95281 0.0240840 K | | |
| N* | 9.72 | 14.41 | 0.94 | 7718 0.0154663 K | | |
| O | 1.97 | 2.56 | 0.41 | 5638 0.0041917 K | | |
| Si | 13.99 | 10.35 | 0.37 | 121603 0.1050690 K | | |
| Pd | 13.73 | 2.68 | 1.75 | 35142 0.0701119 L | | |
| Au | 21.43 | 2.26 | 1.89 | 61526 0.0930259 M | | |
| Total | 100.00 | 100.00 | | | | |

The EDX analysis of the crystal shows that nitrogen is present in the crystal and that the crystal has a yellow coloration indicative of nitrogen doped Sp3 carbon. The other elements shown are from the substrate and the antistatic coating to prevent charging.

FIG. 19 is an image of resulting N-doped diamond. This crystal (> 1,500 microns in size) grew and was doped with nitrogen starting with 6 to 10 nm detonation diamond.

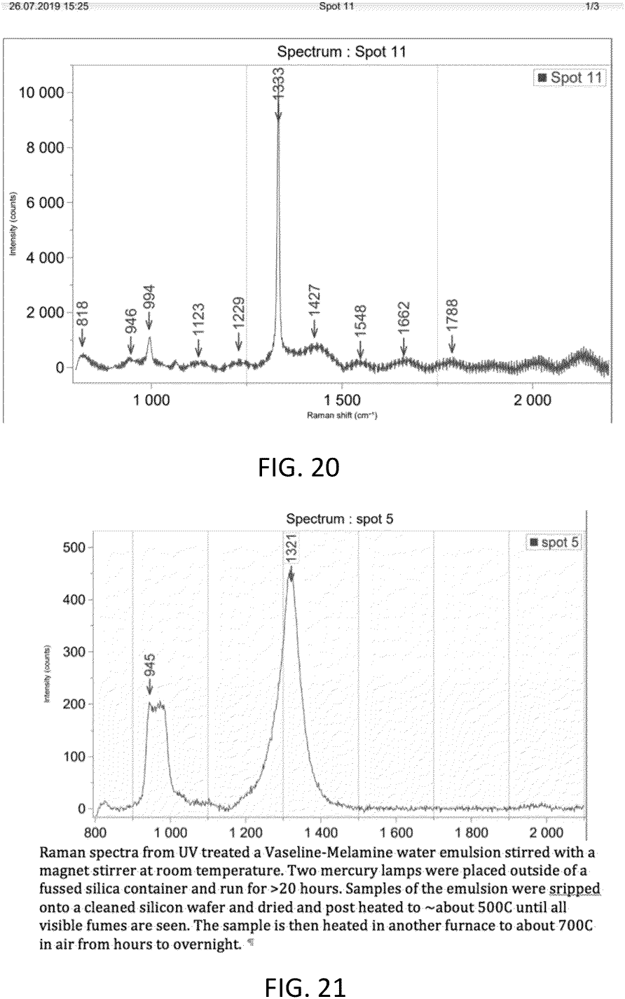

FIG. 20 is a graph of Raman spectra showing the sharp absorption distinctly different from nano diamond powder and like single crystal diamond. Although not all of the particles show such sharp Sp3 presence, this process has been repeated many times and produced similar results with doping and without doping and somehow hydrocarbons are transformed to a 3D bonding configuration at low temperature in the presence of an energy source and in particular a hydrogen source such as water and or alcohol. The transformation of Sp, Sp2, carbons to Sp3 has been found to take place.

### Experimental Example 7

In this experiment, the target material (or sample) was prepared from petroleum jelly and Melamine in a water emulsion with a drop of soap and treated with UV light while being stirred with a magnet stirrer.

In an initial step, the experiment involved mixing petroleum jelly about 3 parts to about 1 part Melamine in water. Subsequently, the mixture was treated with intense ultrasonics for about 5 seconds to about 15 to 30 seconds with as drop or two of soap for producing an emulsion of the mixture. Subsequently, the mixture was placed in a fused silica container and stir with a magnetic stirrer. A UV light was applied from two mercury lamps from outside the container through the fused silica that is transparent to the UV into the mixture for about 20 hours.

FIG. 21 is a graph (along with description) of Raman spectra of the resulting product of the experiment.

### Experimental Example 8

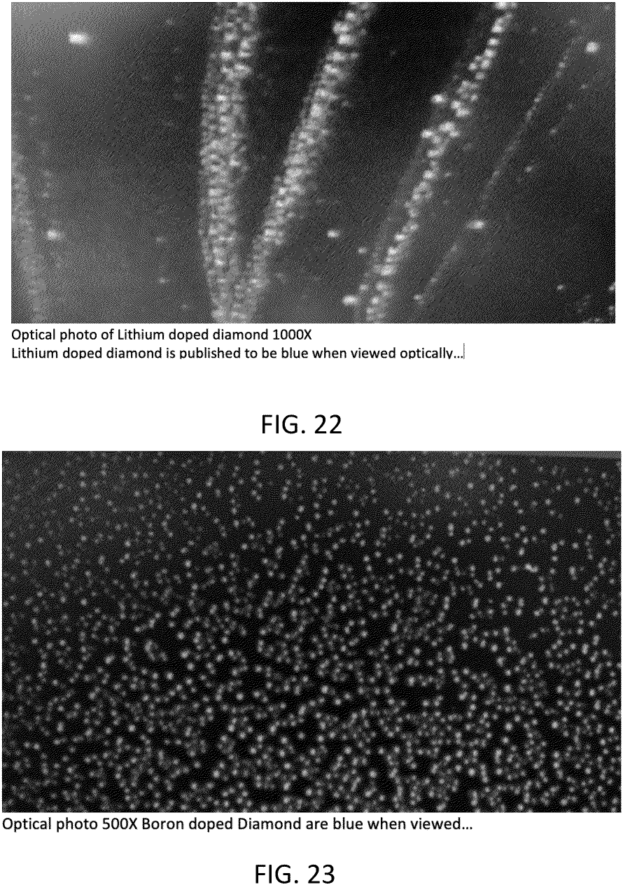

In this example of doping Sp3 carbon, lithium carbonate was mixed with petroleum jelly, water and ethyl alcohol. This mixture was treated as in Experimental Example 3. It is known to those in the art that Li doped Sp3 carbon is blue. FIG. 22 is an image of the resulting product along with description.

### Experimental Example 9

This experiment involved synthesis and boron doped Sp3 carbon. Steps of the experiment included: mixing boric oxide with Vaseline, water and ethyl alcohol; treating with a intense ultrasonics, producing an emulsion for about 20 seconds a drop of dial soap; and heat treating the resultant mixture at 550C until vapors cease to be observed and then put into an air furnace at 750C until all carburized material is removed from hour’s to10’s of hours.

FIG. 23 is an image showing blue crystals micrometers in size with the color of blue diamonds.

### Experimental Example 10

This experiment involved boron doping of carbon fibers by electrolysis. Steps of the experiment included: placing carbon fibers acting as the cathode in a bath of pure water with dilute HCl as and electrolyte; adding boric oxide to the bath; providing a counter electrode of platinum as the anode of the electrolytic bath; applying a DC current to the electrodes at a voltage of about 10 volts and a current of about 5 amps; observing vigorous bubbling with hydrogen forming at the cathode (-) (the carbon fibers) and oxygen at the platinum (+) anode; allowing the process to run 10 to 30 minutes; and heating the resulting fibers in air at about 750° C. for hours.

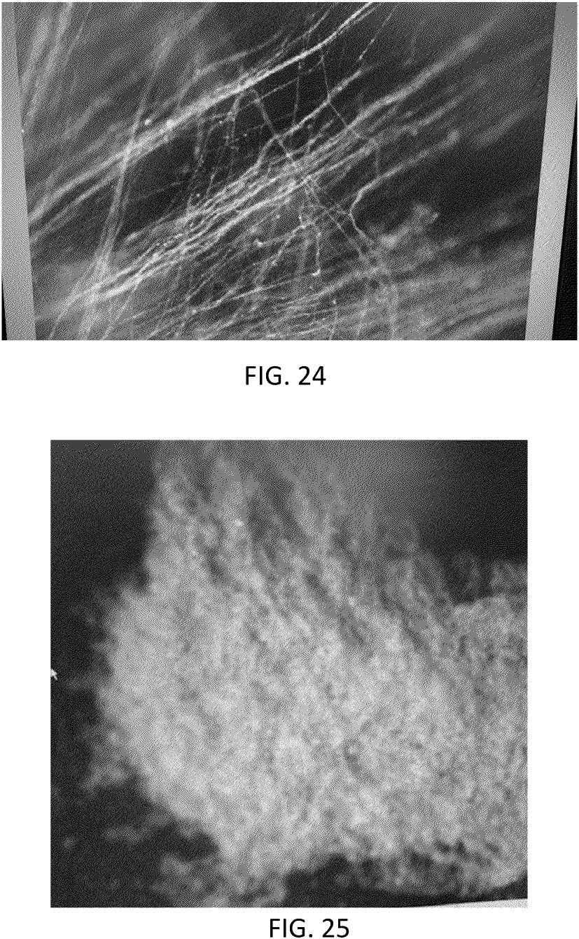

FIG. 24 is an image at 100X magnification of the blue transparent fibers that scratch sapphire.

### Experimental Example 11

This experiment involved formation of sulfur doped Sp3 carbon. It is noted that sulfer has been reported to be incorporated into the diamond structure and act a dopant and is reported to be Yellow in color. This experiment produced a diamond structure with sulfur incorporated into the lattice such that the color of the Sp3 crystal is colored with shades of yellow to brownish yellow among others. Captured images show the effect. The method involved incorporation of nitrogen, boron, lithium and possibly sulfur. The following data reports the current information that supports the sulfur inclusion observations.

Steps of the experiment of incorporating sulfur into the carbon Sp3 structure included: mixing a sulfur containing hydrocarbon and thiophene with petroleum jelly and/or ethanol and water; and treating these linear and/or cyclic hydrocarbons with the potential dopants are treated with energetic processes such as extrusion, or UV radiation.

FIG. 25 is an image at 100X magnification of thiophene only with UV light.

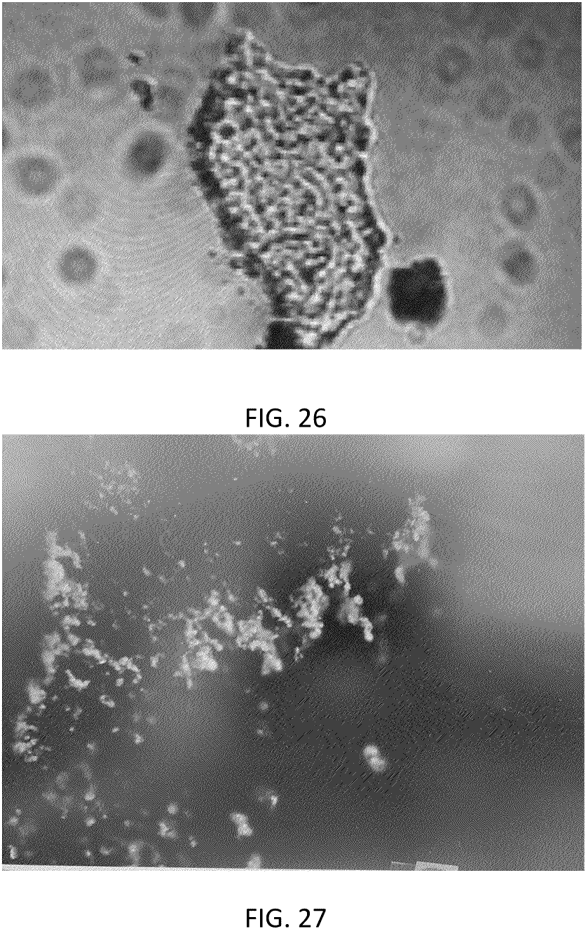

FIG. 26 is an image at 1000X magnification of the crystalline product where thiophene was used as the target material and the process was applied with UV light.

### Experimental Example 12

This experiment involved shearing for application of energy. Particularly, this experiment involved extreme shearing extrusion produced with a high speed rotational tool. The result transformed the target material of Sp2 to a different target material of Sp3.

In the experiment, a powerful shearing force was applied to Sp, Sp2 and Sp3 bonded carbon molecules with mediating agent to produce an extreme condition for the transformation and crystal growth. The shearing effect of two surfaces rubbing against one another in a rotational or in sliding motion with the target and mediating agent, transformations the target material to the Sp3 product. To apply the shearing force, tools such as Dremel (rotation speeds of zero to 38,000 rpm), drills (zero to about 1,800 rpm), as well as dental tools (zero to 250,500 to 400,000 rpm and even to as high a 1,000,000 rpm can be used to excite the process of transformation. Other example applications of force include wafer polishing, rotating rock polishing systems, ball milling, when the conditions of the previous examples are applied.

Steps of the experiment included: mixing carbon (99.999% pure) with water and ethyl alcohol to form a mud-like product; treating the mud-like product with a Dremel tool at 38,000 rpm from 15 to 20 seconds; and removing and heating the resulting material in an air furnace at 750° C. to remove any unreacted black Sp2 carbon to leave a transparent crystalline residue that scratches sapphire.

Prior to this work, under less extreme conditions, where Sp3 carbon was formed and showed the diamond spectra by Raman Spectroscopy. This surprising new discovery is that conversion to a transparent crystal that up to this time is almost 100% conversion that remain crystalline when heated to ~about 700C in air to remove the Sp2 black carbon.

All showed the rapid transformation from the initial black conductive state to a transparent crystalline insulating state. It appeared that most of the material amazingly transforms.

FIG. 27 is an image at 200X magnification after 3 to 5 second treatment of a carbon powder mud (water/alcohol) with a Dremel tool at 38,000 RPM.

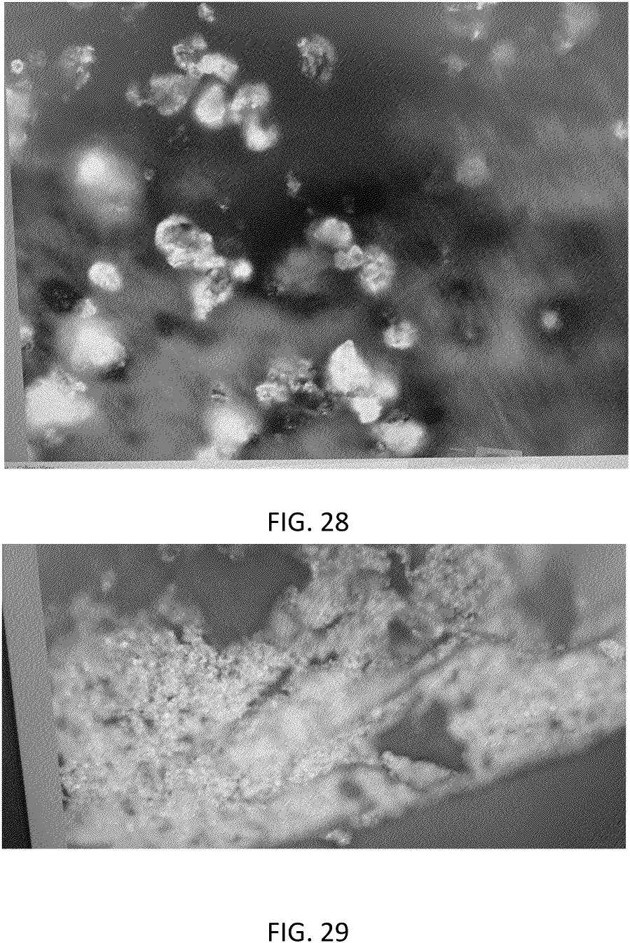

FIG. 28 is an image at 500X magnification showing transparent crystals of carbon after 3 to 5 seconds treatment with a Dremel tool at ~38,000 RPM.

FIG. 29 is an image at 200X magnification showing that the crystals are transparent and relatively uniform in size by the shearing action of the Dremel tool.

As a resulted, the resulting target material produced scratches in sapphire. This was resulting from the transformed Sp2 carbon to Sp3 carbon by treating with a Dremel tool at 38,000 RPM for a few seconds.

### Experimental Example 13

This experiment involved the synthese and growth transformation of a petroleum jelly / water / alcohol mixture to Sp3 carbon (diamond). Steps of the experiment included: thoroughly mixing about 95 parts petroleum jelly with about 5 parts water and alcohol in a container; placing the burr of a Dremel tool in contact with the mixture and operating up to and at about 38,000 rpm for about 15 to 20 seconds; removing the product and heating to vaporize all volatile material to 750C from about minutes to hours. The resulting product was observed to be crystalline with some crystals greater than 2500 microns, transparent and scratches sapphire.

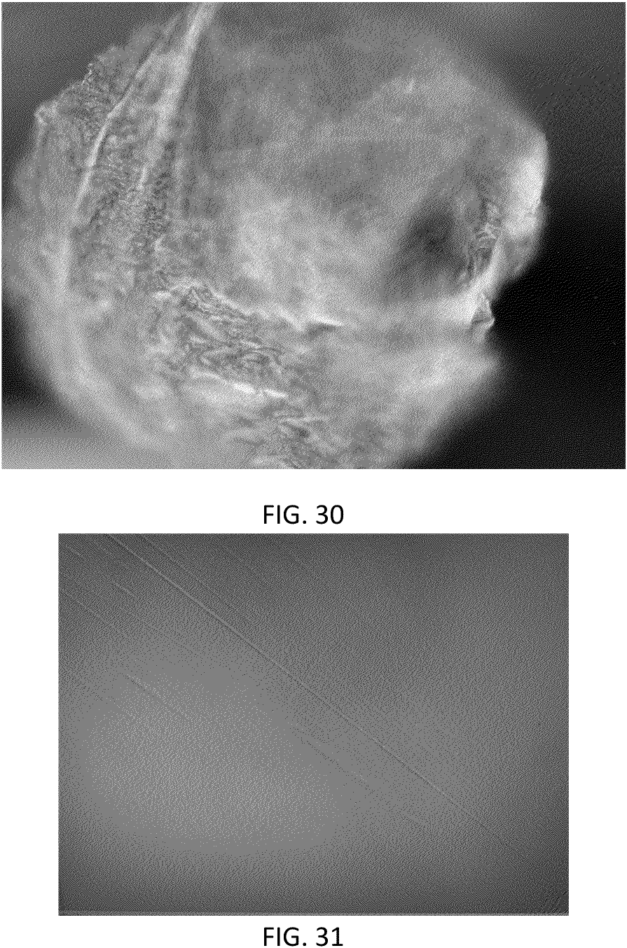

FIG. 30 is an image of 1000X magnification showing transparent crystals in seconds from petroleum jelly hydrocarbon with ethanol and water as starting materials. It was observed that the length of the crystal was greater than 2,500 microns.

FIG. 31 is an image of 500X magnification showing scratching of sapphire as an indicator of a material transformation to Sp3 carbon.

FIG. 32 is an image of 1000X magnification of transparent material produced from petroleum jelly with a Dremel tool at 38,000 rpm in seconds at room temperature. The sample was heated at 727° C. for several hours.

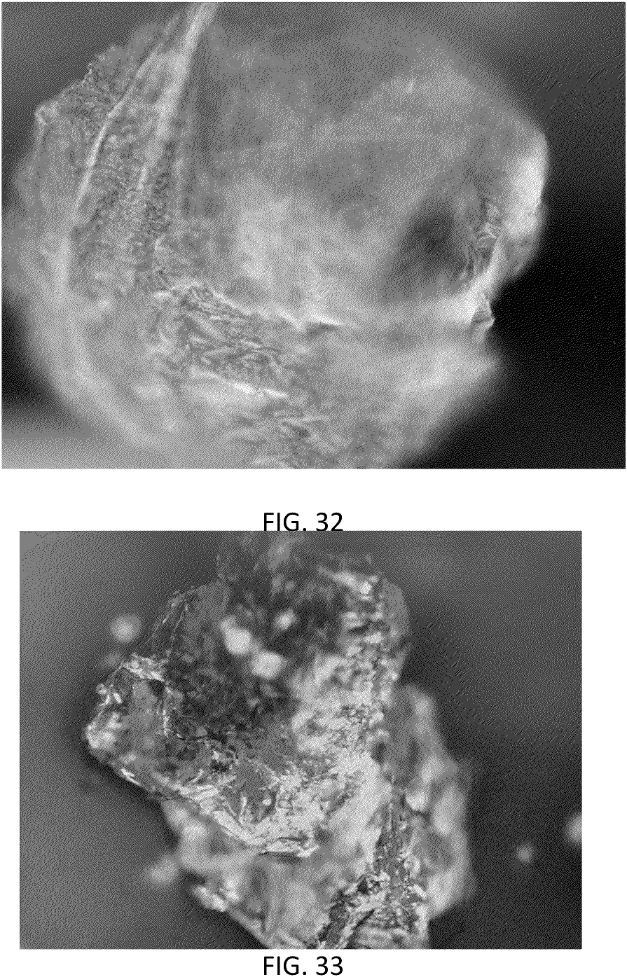

FIG. 33 is an iamge of 1000X magnification of extreme/extrusion E2 of petroleum jelly. The material was transformed in 4 seconds.

### Experimental Example 14

This experiment involved extreme extrusion with pure carbon and trace water / alcohol. Extreme/Extrusion was examined with a close fitted smooth ceramic rod fitted to a cylinder provided by TriboFilm Research Corp. instead of using a Dremel at 35,000 rpm, a drill with speed of 1500 rpm was used. The objective was to examine various approaches to produce Sp3 carbon from various sources of carbon and hydrocarbons as well as doping and apply to other materials.

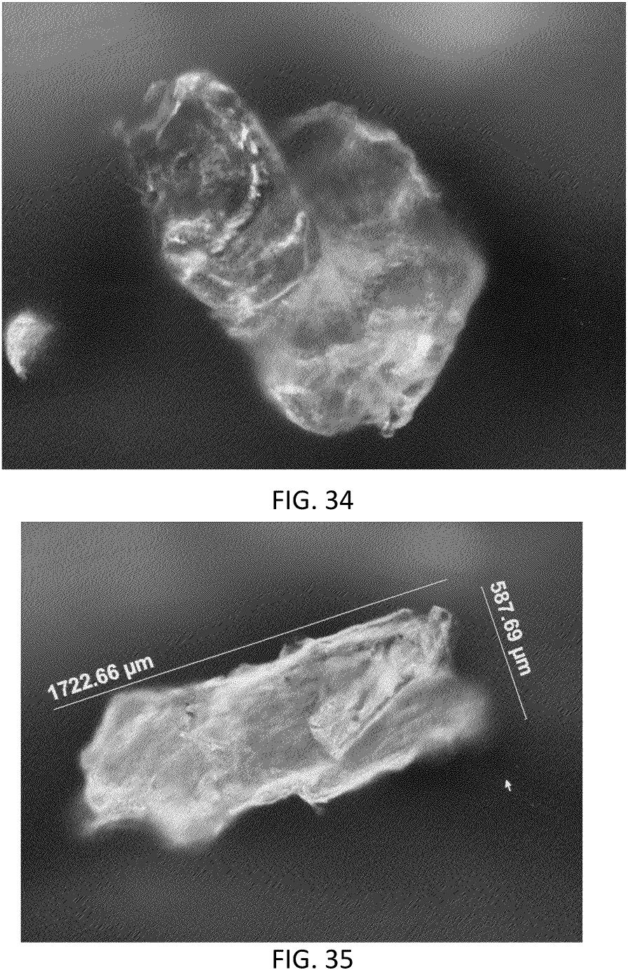

Captured images shows results produced from use of pure carbon with trace amounts of water and ethyl alcohol that was sheared and extruded with a drill at 1500 rpm for about 15 seconds. As a result, micron size transparent apparent high index of refraction crystals were formed. The material was heated to 750C from 15 to 30 minutes in an air furnace. Numerous crystals were formed and some over 1,500 microns of high optical transparency a high probability to be single crystal. FIG. 34 is an iamge of 1000X magnification of extreme/extrusion of pure carbon powder transformed in about 15 seconds with a drill at 1500 RPM. FIG. 35 is an image showing signs of extrusion/shearing with elongated growth.

### Experimental Example 15

This experiment involved synthesis and growth of diamond on nanodiamond nuclei by electrolysis. This process involves applying the processes of the previous examples, and detonation nanodiamonds were grown from nanometer size diamonds to diamonds that are hundreds of microns by the following steps.

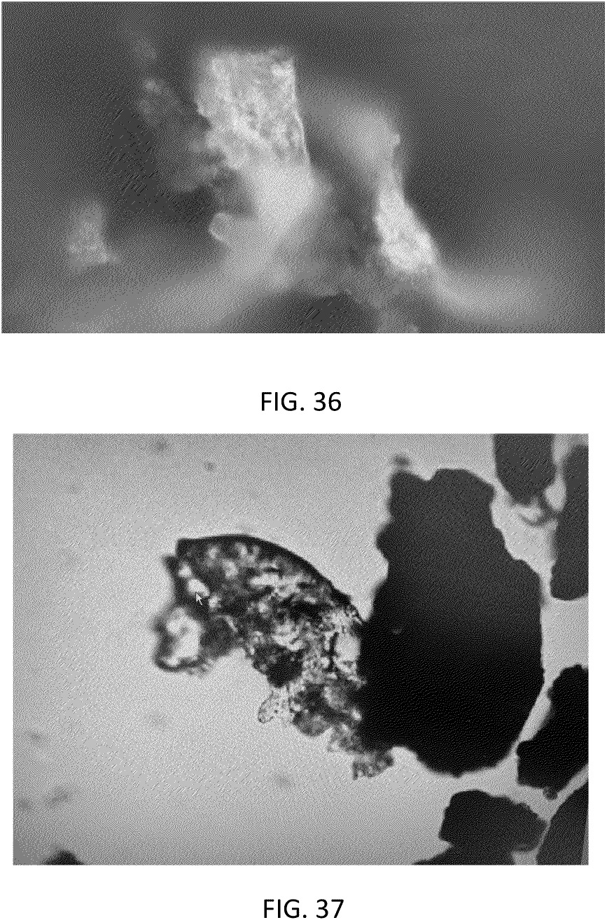

Purchased nanodiamonds were placed in a container with platinum electrodes in water with an electrolyte of HCl. The negative electrode (cathode) was placed in contacted and surrounded with the nanodiamond particles and the positive electrode was set a distance apart. At voltages about 6 to 15 volts was applied far above the overvoltage for hydrogen generation. Vigorous bubbling took place at both platinum electrodes with hydrogen generated at the cathode and oxygenated at the anode. After 5 minutes and about 30 minutes and longer at times, the material was removed separated from the liquid and dried. Images were captured that show a growth of the nanodiamond crystals to micron and greater sizes. For example, FIG. 36 is an image at 500X magnification showing the crystal growth from nanodiamonds to crystals hundreds of microns in size.

### Experimental Example 16

This experiment involves electrolytic growth and lithium doped detonation nanodiamond. The experiment includes the steps of: mixing lithium carbonate with detonation diamond from 6-10 nm as a mud; placing close and touching the mud to a Pt cathode in an electrolytic cell with HCl as the electrolyte and an anode of Pt; applying DC voltages from 6 to 10 volts and about 4 to 6 Amps where vigorous bubbling of hydrogen takes place with contacting and about the nanodiamond; and continuing the process for the time period of minutes to hours. It was observed that the doped crystals are greater than 1000 microns.

FIG. 37 is an image of 500X magnification showing nano size detonation diamonds grown to micron size crystals and doped with lithium producing blue colored crystals.

### Experimental Example 17

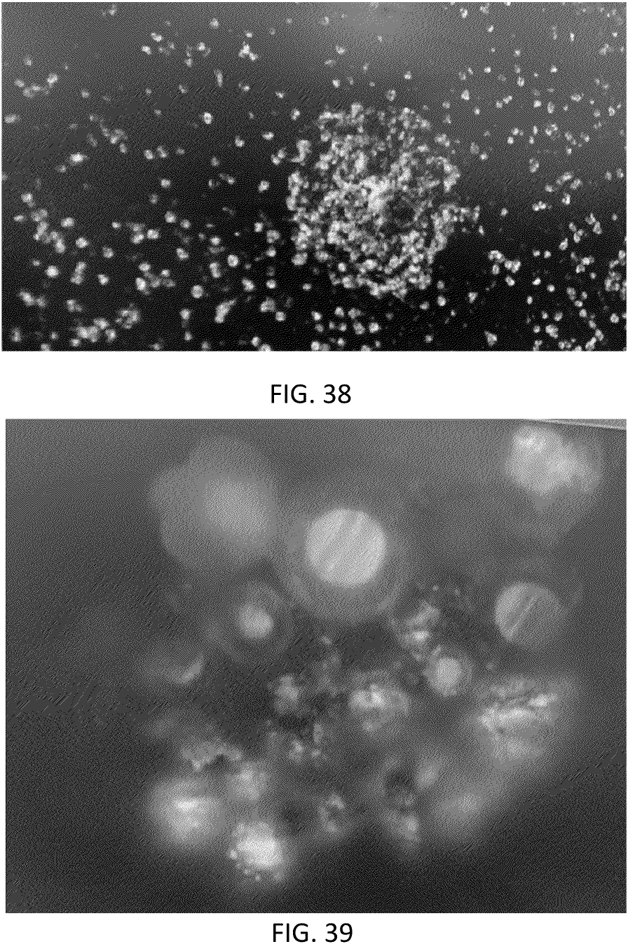

This experiment is similar to others but with nanocarbon mud with lithium dopant from a lithium salt Li₂CO₃. The carbon mud was in contact with the cathode where hydrogen is vigorously being generated. FIG. 38 is an image showing resulting product.

### Experimental Example 18

This experiment involved producing nitrogen doped Sp3 by application of electrolysis. The experiment includes the steps of: providing carbon powder mud in water with NH₄Cl acting as an electrolyte and as the source of nitrogen; contacting a Pt cathode to the carbon mud; and providing conditions the same as other examples provided herein (such as Examples 11, 12, and 13). In this example, nitrogen is incorporated into the transformation and crystal growth of carbon to nitrogen doped Sp3 crystals of carbon.

FIG. 39 is an image of 500X magnification of the resulting product. Several hundred-micron crystals were grown and nitrogen doped from nano-carbon powder. The size of the grown crystals is approximately 1000 microns.

### Experimental Example 19

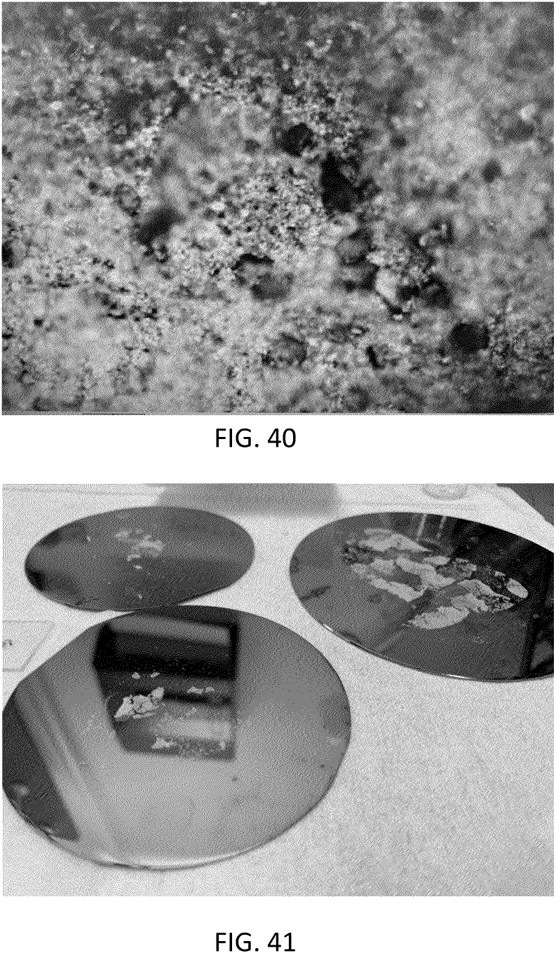

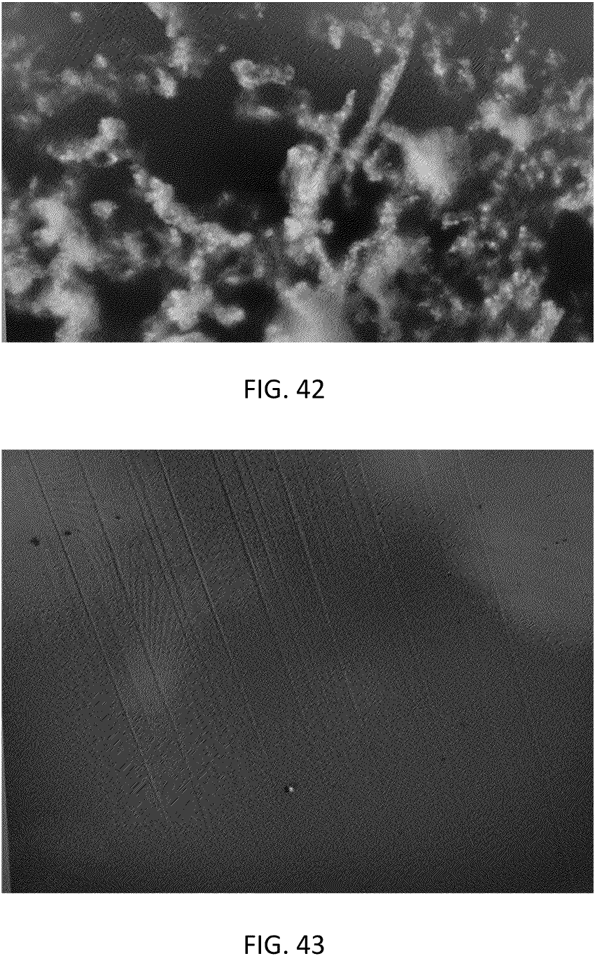

This experiment involved extrusion of Nylon. FIG. 40 is an image of 500X magnification of the resulting product from extrusion of Nylon plus water and ethyl alcohol and treated with a Dremel tool at 38,000 RPM.

### Experimental Example 20

This experiment involved extrusion of a polyethylene terephthalate (PET) food container. This experiment demonstrated that polymers such as PET can, when stressed and strained, can transform to an Sp3 form of carbon that can withstand 750° C. for 24 hours. This resulting product can be transparent solids that survives hot H₂SO₄ and HF and scratches sapphire.

The following looks to demonstrate the relationship of the extrusions of PET in commercial containers to the production of Sp3 carbons. This work will show that a PET container was (1) extruded to the original shape by the manufacture; and (2) then further extruded and shrunk after exposure to a dish washer cycle. The hot water treatment shrunk and reshaped the container further.

The experiment includes heating the target material to about to 500C on a hot plate in a hood until fumes were no longer detected and further heated in a furnace to 750° C. for several hours. The residues found were treated in HCl and followed by hot concentrated sulfuric acid with concentrated HF. It is understood that under these conditions only Sp3 diamond will survive.

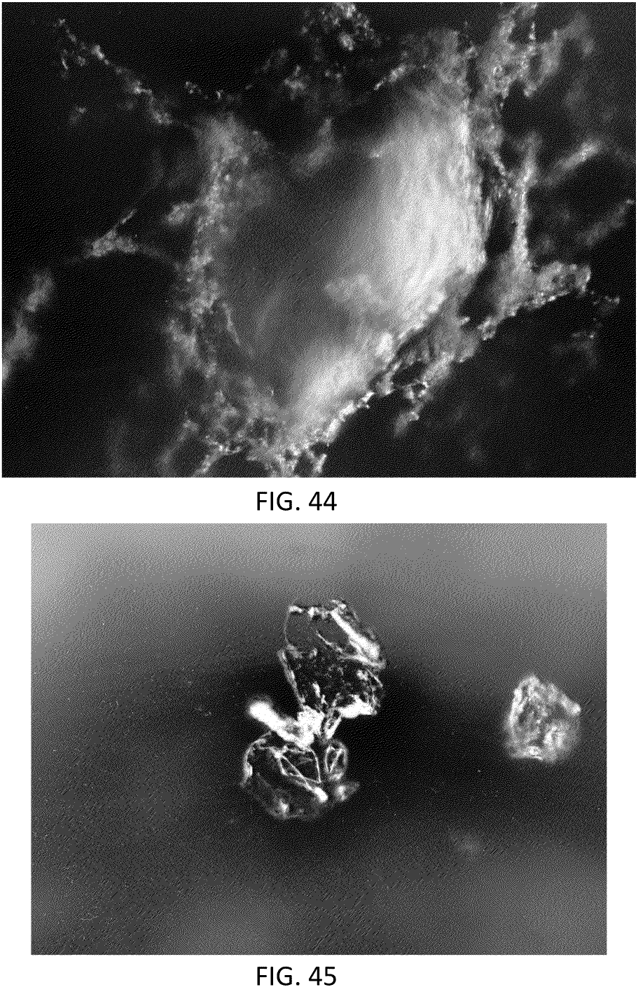

FIG. 41 is an image showing resulting residues treated with hot conc. HCl and further with hot concentrated H₂SO₄ with Conc, HF. Particles that survive this treatment from a hydrocarbon source are only a Sp3 form of carbon.

FIG. 42 is an image showing that the resulting particles are transparent and scratch sapphire. Further, FIG. 43 is an image showing residue from the treated PET container scratched sapphire.

### Experimental Example 21

This experiment involves nitrogen doping with a compound containing nitrogen. This example demonstrates the doping of the Sp3 product via the target material containing the dopant and with the mediator water and or ethyl alcohol acted upon by an instant energetic process, shearing with intense ultrasonics resulted in yellowish crystals indicative of nitrogen doped Sp3 carbon. FIG. 44 illustrates an image with 500X magnification showing the yellow-colored crystals anticipated for nitrogen doped Sp3 carbon that scratches sapphire and stable at ~700° C.

### Experimental Example 22

This experiment involves atmospheric plasma crystal growth and doping. The method provides for the transformation of hydrocarbon compounds to crystalline solids as well as doping the growing crystals simultaneously with a dopant from an organic compound containing the dopant. The method includes a plasma process that draws vapors together into the plasma by flowing argon plasma. FIG. 45 is an image of 500X magnification of crystal produced by atmospheric plasma treatment of vapors of n-heptane and carbon disulfide. This resulting material scratches sapphire.

### Experimental Example 23

This experiment involved conversion of naphthalene to diamond at room temperature. For example, moth balls were used as a target material. An objective of the experiment was to examine another hydrocarbon, naphthalene, to convert to diamond at room temperature with UV light and H₂O. With the high vapor pressure of the naphthalene, the thought is that vapor phase conversion can take place thereby producing nano-diamond.

The experiment includes the steps of: placing a small amount of naphthalene in a chamber of fused silica with a few drops of water; placing a mercury lamp over the chamber and covering with aluminum foil; radiating the sample for about 10 hours with the mercury lamp; and heating the sample to remove the volatiles to 650° C. for about 3 hours. In the resulting product, several clear transparent crystals were observed and were found to scratch sapphire.

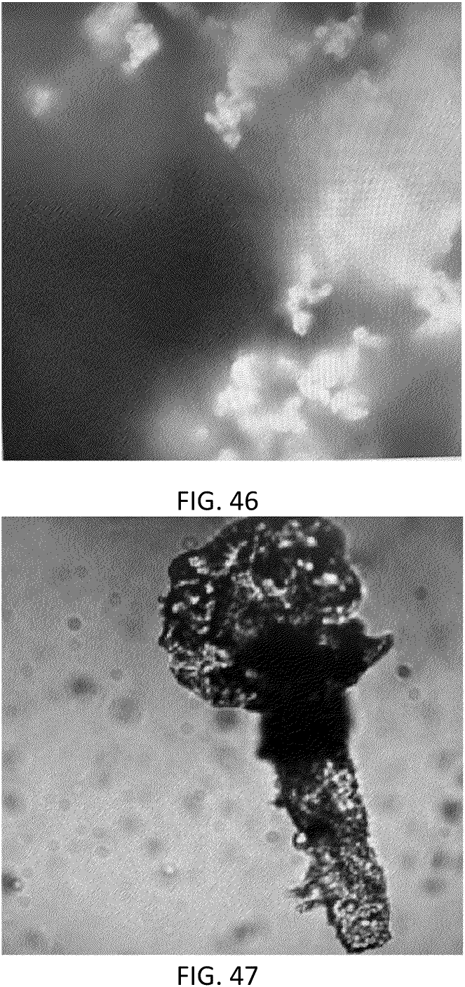

FIG. 46 is an image of 500X magnification showing resulting crystals.

FIG. 47 is an image of 500X magnification with transmitted light. The dark areas are due to the thickness of the sample.

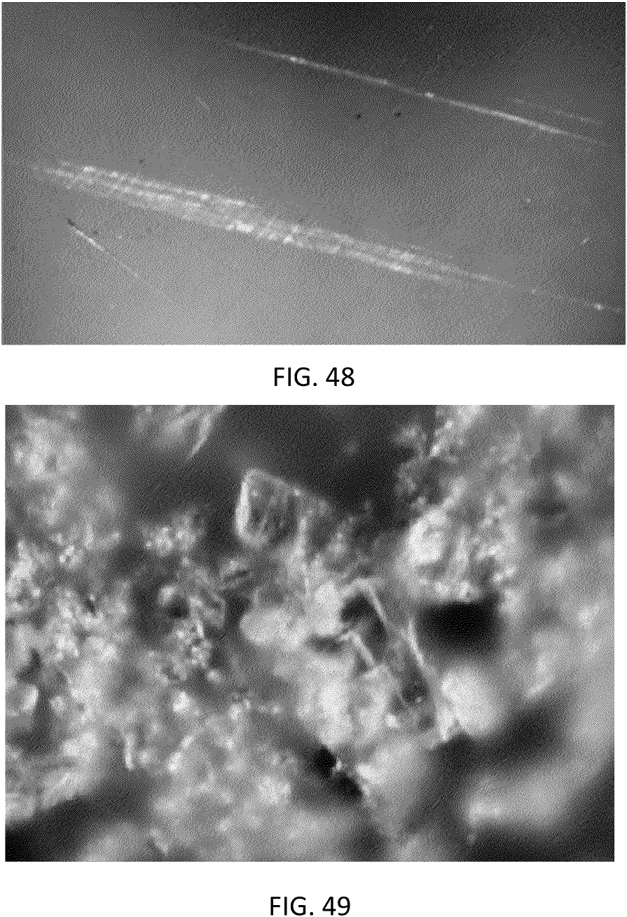

FIG. 48 is an image of 500X magnification showing a result of the product material scratching sapphire.

### Experimental Example 24

This experiment involved use of commercially produced diesel-like oil produced from the recovery of automotive rubbers tires and transformation of it to Sp3 carbon (diamond). The experiment includes the steps of: putting about 1 cc of oil with 2 drops of ethanol into a container; applying the gist of the Dremel tool to the oil and between surface and the tool for ~15 seconds; removing the resultant material by adding acetone and extracting the thickened oil and putting several drops onto a fused silica substrate; heating in air to drive off the volatiles on a hot plate and then in a furnace to 750° C. for about 1 hour; placing the dried crystals on a single crystal sapphire wafer; and applying a force with a SS spatula with a scratching motion.

A target material used in the experiment contains oil recovered from the controlled oxidation of rubber tires complements. The hydrocarbon oil is about the consistency of diesel fuel but with about 9000 ppm sulfur as from the thiophene family of compounds. The oil target material was treated with the Dremel tool as in above described examples for about 15 seconds and heat treated at 750° C. for about 30 minutes. The residue was composed of transparent crystals that are yellowish in color and scratches sapphire.

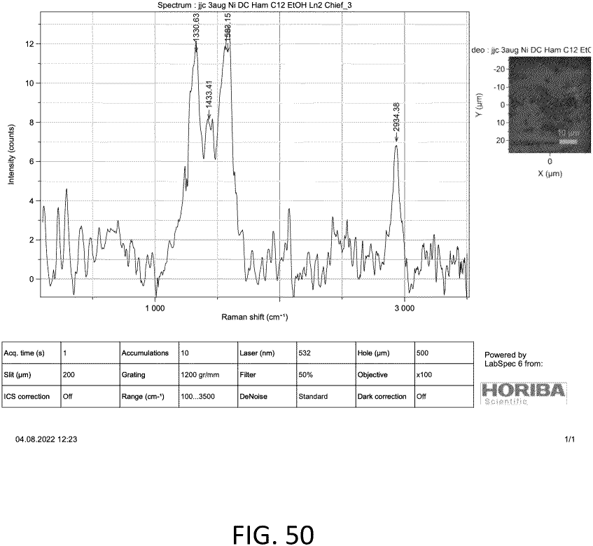

FIG. 49 is an image of 500X magnification of transparent crystals produced by the treating diesel-like oil with a Dremel tool for about 15 seconds and after heating in air for about 30 minutes. It was also observed that the resulting material can scratch sapphire.

### Experimental Example 25

In other experiments with extreme shearing surfaces, it was discovered that as the Sp3 material formed under intense contact with the surface the product material transformed and cold welded to the surface. That is bonded to the surface as a transparent and smooth surface.

In an experiment, an article was coated with Au/Pd for SEM/EDX analysis which showed to be only carbon. The experiment includes the steps of: converting and transferring the target material as transforming to Sp3 carbon to another surface by cold welding; mixing the target material of petroleum jelly with a mediating fluid; applying the mixture to the article, a dense polycrystalline alumina substrate, to be coated and or to the surface to the tool that supplied the instant energy; and applying force that makes intimate contact with the article that will torque the tool to slow it down by the shearing frictional force between the tool and the article.

### Experimental Example 26

This experiment involved in situ functionalizing of a surface of a target material. The experiment includes the steps of: mixing a hydrocarbon with fluid with predetermined functionalities to form an emulsion; applying instant energy to the mixture; and separating the product from the mixture with a functionality in accordance with embodiments.

Instant energy application can be entirely or solely applied to target materials in the experiment described herein by ultrasonics. In another example, instant energy may be applied by rapid stirring.

### Experimental Example 27

This experiment demonstrated the power of out diffused atomic hydrogen from solids such as Nickel that has been loaded with atomic hydrogen. In the method, a nickel slug was electrolytically infused with hydrogen by electrolysis, cooled to liquid nitrogen temperature submerged in dodecane, encasing it and put back into liquid nitrogen for 30 minutes. These steps were repeated. The objective is to check if having the target hydrocarbon (in this example dodecane and ethyl alcohol) in contact with atomic hydrogen loaded material (Ni) is struck with a hammer (HAMMER SHOCK) several times producing crystals that after heating to 750C in air produced the following Raman spectra and scratched sapphire. After 30 minutes, crystals are found on the nickel, removed and after heating in air at 760C for over 30 minutes, scratched sapphire. FIG. 50 shows a graph of Raman spectra of the product.

### Experimental Example 28

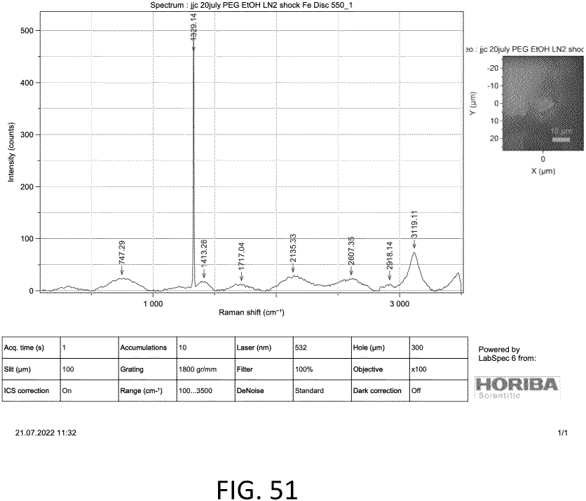

This experiment involved use of Polyethylene Glycol (PEG)/ Ethyl Alcohol (EtOH) as a target material with energy applied as a hammer shocked at liquid nitrogen temperature -198° C. The sample can be prepared and processed in accordance with any other suitable example experiments described herein. It is noted that other target materials demonstrated similar results. FIG. 51 shows a graph of Raman spectra of the product.

### Experimental Example 29

This experiment involved use of a nickel slug and niobium sheet loaded hydrogen samples. The nickel slug and niobium sheet loaded hydrogen samples were rinsed in deionized water dryed and put in pure water while in contact with PH paper indicator. The niobium sample was gently sanded in a portion of the sheet. An untreated Ni slug, the Nb and treated Ni slug were put in water as described above and compared as is shown below.

Captured images of the experiment show that within seconds of contact the treated samples in the water in contact with the litmus paper turned BLUE indicating the water became basic while there was no indication of reaction with the untreated Ni sample and the outline on the Nb sample that was gently polished.

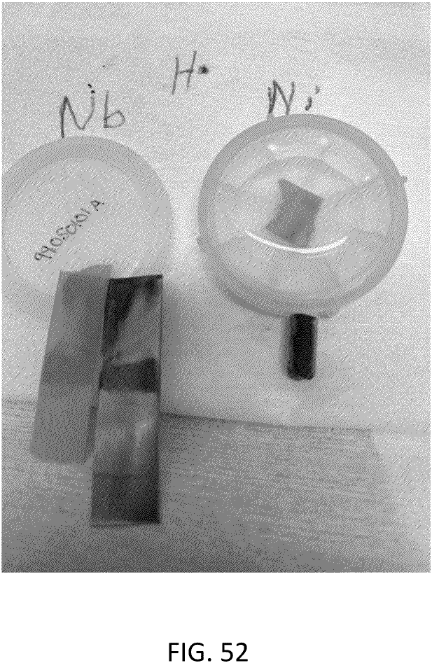

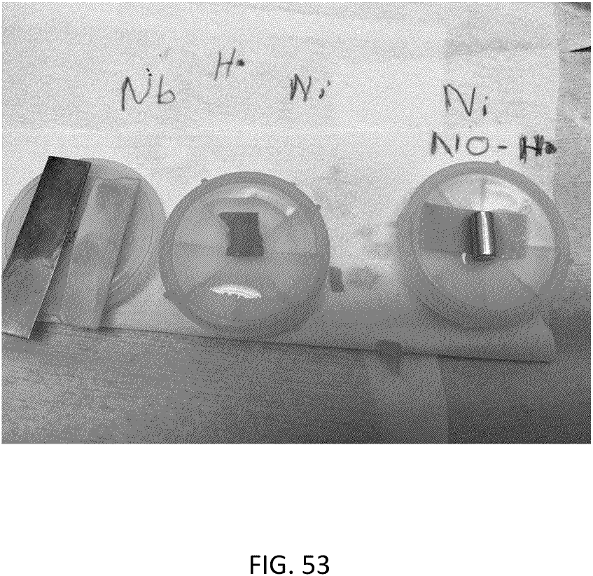

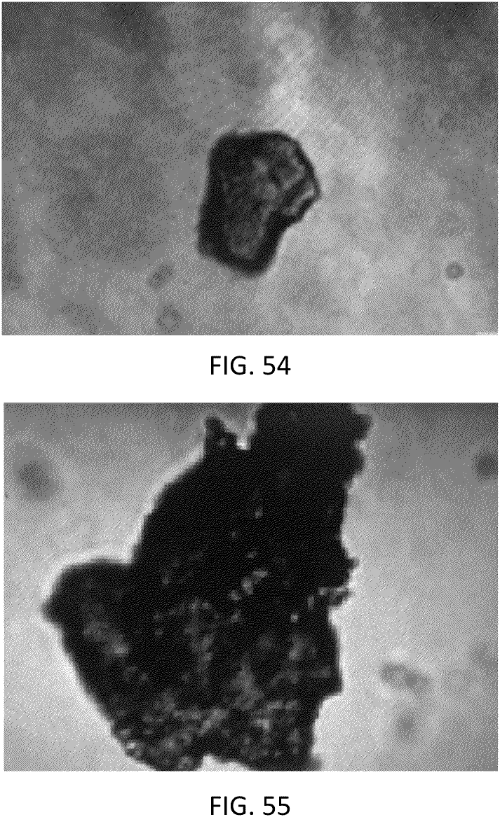

FIG. 52 is an image showing containers with resulting samples that demonstrate the areas that have interacted with water. Also, FIG. 53 is an image showing on the far left the Niobium sheet dark and light area that has a corresponding image on the litmus paper. The white area is a result of light sanding of the surface. The sample is reconfigured from the previous figure where the correspondence is much clearer. The middle sample is the transformed litmus paper only shown in the previous photo with the Ni sample. The sample on the far right is Ni pure from the same source but without being charged with hydrogen by electrolysis and hours of contact with the water without reaction. It is believed that the reactions shown above are governed by non-Arrhenius reaction rate behavior, and demonstrate a quantum tunneling of atomic hydrogen as the principal actor at low temperatures from about room temperature down to liquid nitrogen temperatures and below. The indication of reactions of atomic hydrogen from hydrogen infused materials is another method that the other instant energies produce when initiated.

While examining samples shown in Example 27 the positive pole of a multymeter was attached to the hydrogen loaded Ni sample and the negative electrode to the untreated Ni sample. A red electrode was attached to the hydrogen loaded Ni. The black electrode is attached top the untreated Ni and the liquid is pure water. The voltage forms immediately to about 0.31 volts. What was noticed is that the voltage started to steadly decay indicating that this reaction with water is showing the out diffusion rate of the atomic hydrogen. The voltage also was found to increase when warm water was added and resume a decay. This observation opens up the study of diffusion rates from different materials with different crystal structures as well as a function of temperature. The voltage of the cell decays in time. Further, both voltage and the Ph are observed together. These simple laboratory observations open up a need-to-know further work as a resultant from these results. The out diffusion of hydrogen reacting continuously with a water hydrogen producing release of the OH ion into solution producing a basic solution. The voltage decays and demonstrates a diffusion rate of the atomic hydrogen being delivered and extracted from the surface. The reaction and its rapid rate, provides insight into the reactions of aforementioned example experiments with targets of carbons, hydrocarbons and the like. With the knowledge and understanding of the incorporation of the other isotopes of hydrogen, deuterium and tritium, it can be seen from this work, smilar results are expected.

### Experimental Example 30

This experiment involved oxide transformation for growth and doping. The same principals of growth transformation and doping can be applied to other material classes such as oxides. Alumina was explored in this example. Steps include mixing Alumina Al₂O₃ powder with Cr₂O₃ powder with water and ethanol and extruded with nuts and bolts. The following photos of a Ruby crystal are found. These same results have been demonstrated previously by the author and are not shown here.

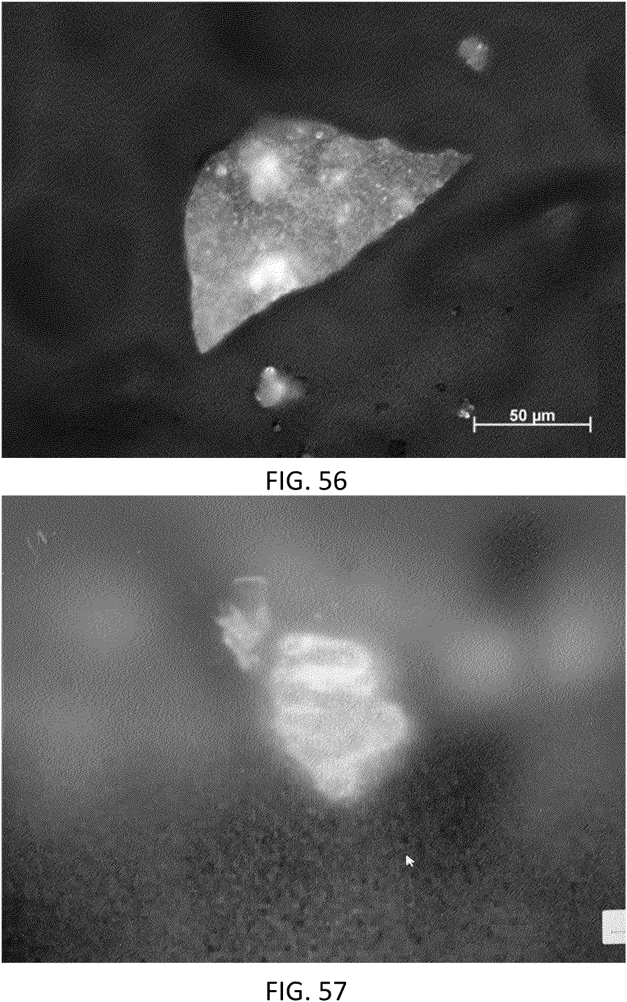

FIG. 54 is an image of 1000X magnification of Cr doped A1203 (ruby). Also, FIG. 55 is an image of 1000X magnification of Cr doped Al₂O₃ powder that grew as well as incorporated the Cr into the lattice producing ruby. FIG. 56 is an image of titanium doped Al₂O₃ at room temperature (Ti-Sapphire).

### Experimental Example 31

Experiments produced crystals are stable at 760 degress Celsius heated in air; scratches sapphire; and shows a Raman spectra with Sp3 character.

An experiment was implemented to examine the electrolysis of pure nickel as the cathode (-) in pure water with platinum contact and counter electrode (+). The objective of this experiment was to have the atomic hydrogen from the surface of the Nickel react with the hydrogen from the water molecule producing H₂ and -OH, which would show basic (blue) on litmus paper and is shown below. In this experiment\, with electrolysis of a Ni-Cr wire coil loaded, the wire with hydrogen and put it in recovered oil from tire recycling, heated the oil to about 50° C. for about 10 minutes. The initial results are provided.

Several experiments were set up to examine the notion that atomic hydrogen exiting from hydrogen absorbing materials such as, but not limited to, steel, titanium, nickel, palladium, and the like can react with a target material such as, but not limited to, carbons, hydrocarbons, oils, and the like at temperatures from above room temperature to liquid nitrogen temperature. Some have also been tested that show evidence of doping at liquid nitrogen temperatures with hammer shock at about 10 seconds reaction time.

In experiments, a nichrome wire was wound into a coil and used as the cathode in the electrolysis of water with HCl as an electrolyte. The anode was Platinum. After about 1 minute, the sample was placed in 5 cc’s of dodecane with ~5 drops of ethanol for seconds as well as warming the wire and repeating the dipping into the dodecane. The sample was rinsed and showed several crystals on the surface of the wire. They were put onto a sapphire wafer, rubbed with a stainless-steel spatula, and shown to scratch sapphire. FIG. 57 is an image at 200X magnification of the resulting product.

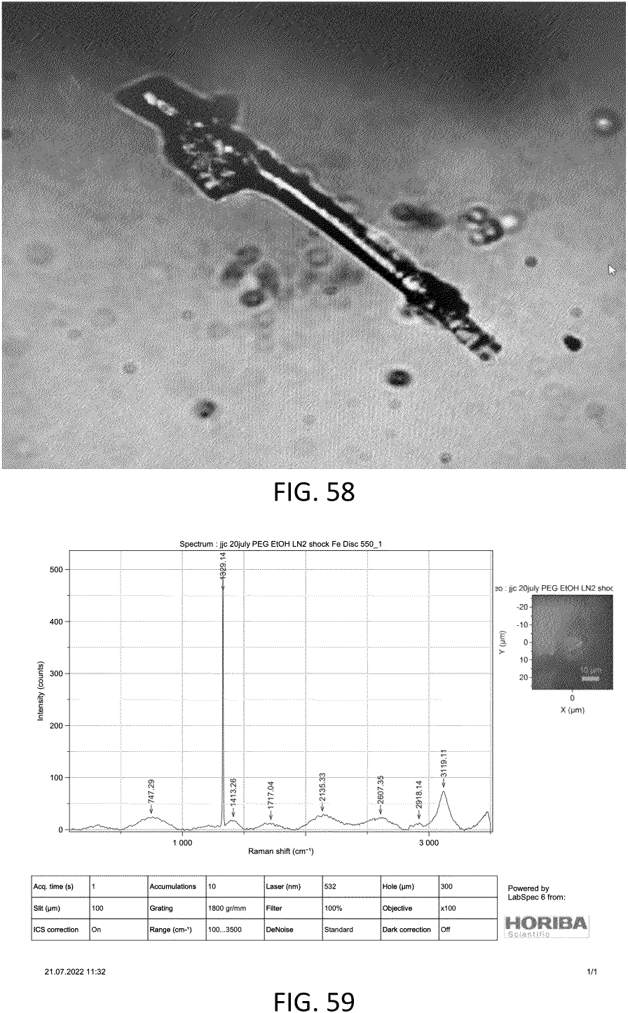

Titanium was chosen since it is known to absorb hydrogen and desorbs as atomic hydrogen on its surface. For example, FIG. 58 is an image of 1000X magnification of a resulting product that demonstrates atomic hydrogen tunneling.

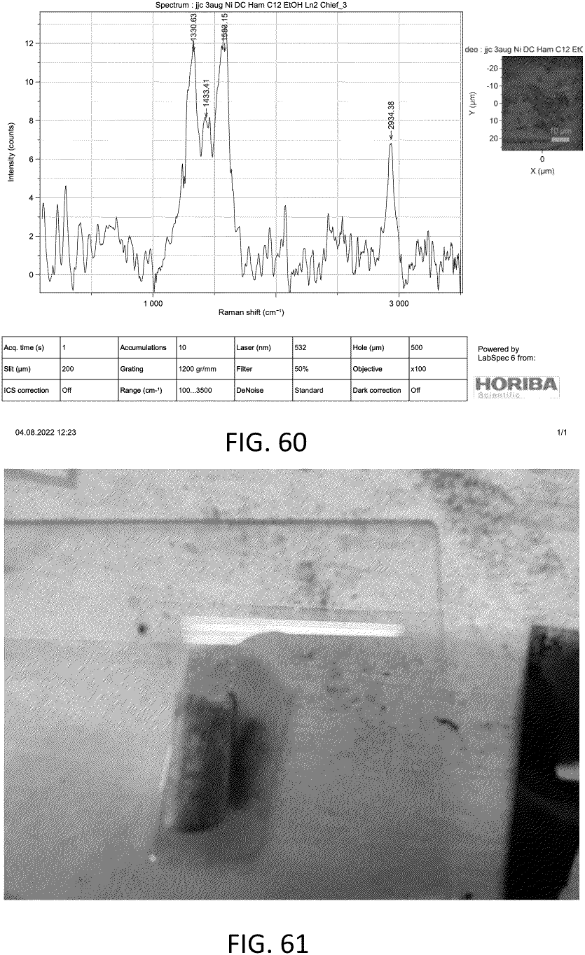

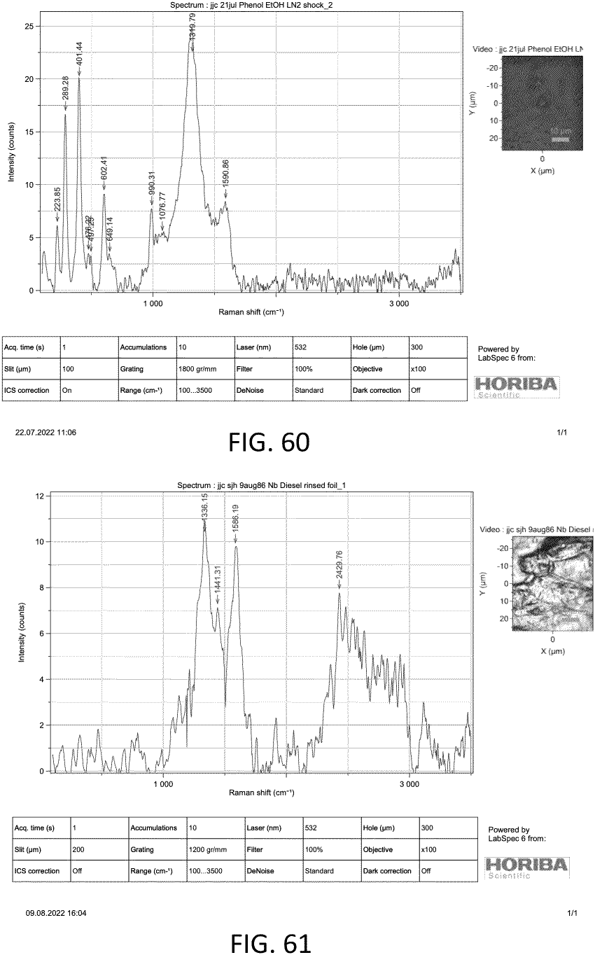

Some of the following are samples “loaded” with hydrogen and believed to exit the metal under energetic impact in contact with a hydrocarbon moledule with an “activating agent” causing atomic hydrogen to exit the metal and react with the targeted material producing a transformation of the target material to Sp3 carbon (or diamond). FIG. 59 is a graph depicting Raman spectra with polyethylene glycol (PEG) / ethyl alcohol (EtOH) / hammer shocked at liquid nitrogen temperature -198° C. FIG. 60 is another a graph depicting Raman spectra with nickel loaded with hydrogen by electrolysis with dodecane C₁₂ and ethanol cooled to liquid nitrogen and hit with an air driven hammer for about 10 seconds.

In another test in an effort to show the expression of atomic hydrogens reactions is to take a nickel-loaded hydrogen sample rinsed in deionized water and put in contact with Ph paper indicator. FIG. 61 is an image showing that within seconds of contact with the litmus paper it turned BLUE indicating the water became basic.

In an experiment, phenol was deposited onto a SS disc and cooled to liquid nitrogen temperature sandwiched between another ss disc. The discs were hammer shocked with about 5 strikes. The Raman Spectra suggests that Sp3 bonding is present.

In another experiment, a strip of niobium was electrolytically loaded with hydrogen by electrolysis for 45 minutes. The sample looked dark to the eye up to the surface of the liquid. A ¼X¼-inch sample was cut away and cooled to liquid N2 and hammer shocked

In another experiment, a nickel slug was electrolytically infused with hydrogen as previously described. Further, it was cooled to liquid nitrogen temperature submerged in dodecane, encasing it and put back into liquid nitrogen for about 30 minutes. This was repeated. The objective was to check whether having the target hydrocarbon in contact with atomic hydrogen loaded material (Ni) with no other activation process just intimate contact would react. After about 30 minutes, crystals are found on the nickel that scratched sapphire. FIG. 61 is a graph of the Raman spectra.

As discussed hereinabove, when hydrogen loaded materials such as Ni, Nb is infused the out diffusion in pure water in contact with the metal and a litmus Ph indicator paper, the paper turns blue indicating a high Ph >12 basic. This means that a hydrogen from the water molecule is extracted leaving excess hydronium ions increasing the Ph. In one of the samples shown below, Ni from the same source that is not infused with hydrogen shows no change in the Ph of the water.

It was shown that the contact areas with the H₂ infused metals and the reaction with the Ph litmus paper. The area on the Nb where there was no apparent interaction with the litmus paper was slightly sanded prior to making contact and matches the litmus paper. It is assumed that the surface sanding somehow blocked the out diffusion in that area. The nickel sample that was used before behaved as it did before. The untreated Ni sample showed no interaction with the water that remined neutral, Ph 7.

It is believed that the reactions shown above are governed by Non-Arrhenius reaction rate behavior demonstrates a quantum tunneling of atomic hydrogen as the principal actor at low temperatures from about room temperature down to liquid nitrogen temperatures and below. The indication of reactions of atomic hydrogen from hydrogen infused materials is another method that the other instant energies produce when initiated.

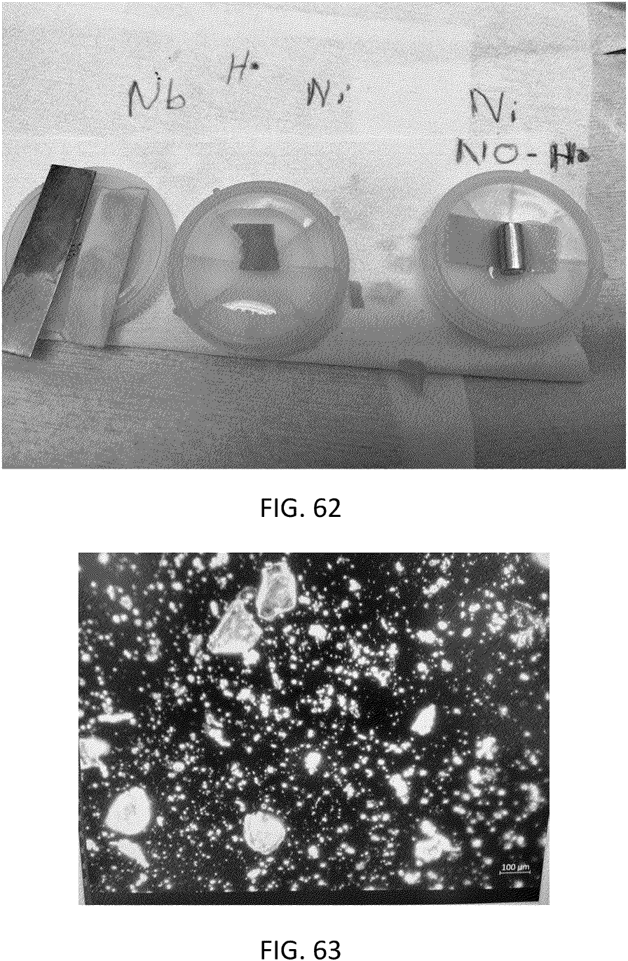

FIG. 62 is an image showing on the far left the Niobium sheet dark and light area that has a corresponding image on the litmus paper. The white area is a result of light sanding of the surface. The sample is reconfigured from the previous figure where the correspondence is much clearer. The middle sample is the transformed litmus paper only shown in the previous photo with the Ni sample. The sample on the far right is Ni pure from the same source but without being charged with hydrogen by electrolysis. This sample represents greater than hours of contact without reaction.

In another experiment, thin film of Nb50—Ir50 on a sapphire substrate was electrolytically treated to infuse with atomic hydrogen. A small area of the wafer was treated for about one minute, rinsed dried and a few drops of ethyl alcohol deposited on the treated area for about 5 seconds. FIG. 63 is an image of 500X magnification of resulting product that shows the crystals that grew on the surface with slight warming of the wafer.

While the embodiments have been described in connection with the various embodiments of the various figures, it is to be understood that other similar embodiments may be used, or modifications and additions may be made to the described embodiment for performing the same function without deviating therefrom. Therefore, the disclosed embodiments should not be limited to any single embodiment, but rather should be construed in breadth and scope in accordance with the appended claims.

1. A method for material transformation, the method comprising:
providing a target material comprising carbon organic hydrocarbon and/or inorganic hydrocarbon;
placing the target material within a fluid comprising a hydrogen source; and
applying energy to the target material such that at least some of the target material is transformed to the same material with a different bonding configuration.

2. The method of claim 1, wherein the target material comprises one of inorganic liquid, solid hydrocarbons, olive oil, mineral oil, diesel oil, canola oil, greases, or polymers.

3. The method of claim 1, wherein the target material comprises at least one of Aluminum, Gallium, Zinc, Indium, or Geranium.

4. The method of claim 1, wherein applying energy to the target material comprises applying energy to the target material for a predetermined period of time such that energy is provided for supporting the different bond transformation.

5. The method of claim 4, wherein the predetermined period of time is one of microseconds, seconds, days in accordance with an amount of energy applied to the target material that transforms the target material that is consistent with the energy source and mode and form of the energy delivered consistent with each form of energy consistent with its nature.

6. The method of claim 1, wherein applying energy comprises applying to the target material ultraviolet (UV) light, mechanical force, shear force, compressive force through extrusion, and or ultrasonics, electrolysis, atmospheric plasma, high electrical fields, hydrogen ionic and/or atomic to create and deliver energetic particles to mediate structural change with respect to the energy source and the fluence from that source.

7. The method of claim 6, wherein impact of the applied energy is instant, local to the target material such that particle release mediates the transformation of the target material to a different stable form at ambient and near ambient conditions without change in an overall thermal energy change to the target material.

8. The method of claim 1, wherein applying energy comprises applying ultraviolet photon energy to the target material that is one of between about 200 newton nanometers (nm) to about 400 nm, or between about 10 nm and about 200 nm in vacuum or inert gas conditions.

9. The method of claim 6, wherein the atoms and molecules of the target material experience mechanical forces that weaken and scissor bond, mediate the transformation of the target material to a different stable form, from liquid nitrogen to ambient and near ambient conditions without change in an overall thermal energy of the target material.

10. The method of claim 4, wherein applying energy comprises one of applying forces that one of force the target material through a die or through rollers; applying mechanical shock and/or shear forces to the target material; and/or applying contact with hydrogen in its activated form ion or atomic.

11. The method of claim 1, further comprising doping the target material.

12. The method of claim 11, wherein doping the target material comprises doping the target material with nitrogen, boron, lithium, sulfur, phosphor(o)us, and/or silicon.

13. The method of 1, further comprising implementing the steps at a temperature between about -198° C. and about and above 400° C.

14. The method of claim 1, wherein the target material is exposed to within a fluid comprises placing the target material in contact with water and/or alcohol vapor, liquid or as a frozen solid and/or a surface to which atomic hydrogen has diffused to.

15. The method of claim 1, further comprising heat treating the target material with the different bonding configuration at between about 500 centigrade and about 750 centigrade in air.

16. The method of claim 1, wherein the target material comprises Sp carbon, Sp2 carbon, and/or Sp3 carbon.

17. The method of claim 16, wherein applying energy comprising applying energy to the target material with the sp carbon, the sp² carbon, and/or the sp³ carbon such that the Sp carbon, the Sp2 carbon, and/or the Sp3 carbon transforms to sp³ bonding configurations for synthesis and/or growth.

18. The method of claim 1, wherein the fluid comprises water, alcohol, atomic hydrogen, or combinations thereof.

19. The target material of claim 1, wherein the target material is transformed, entirely or in part, to Sp3 carbon or mixtures of Sp2 with Sp3 carbon.

20. The method of claim 19, wherein the target material is transformed into a solid crystalline or amorphous and/or material mixture thereof.

21. The method of claim 20, wherein the target material is all or in part single crystal.

22. The method of claim 20, wherein the target material is grown onto a surface other than the target.

23. The method of claim 20, wherein the target material is grown unto itself.

24. The method of claim 20, wherein the target material contains the dopant as part of the hydrocarbon.

25. The method of claim 20, wherein the target hydrocarbon is mixed with a material containing the dopant.

26. The method of claim 20, wherein the dopant concentrations exceed equilibrium conditions.

27. The method of claim 1, wherein synthesis of the target material is grown on a substrate, heteroepitaxial, or on a substructure in kind, homoepitaxially.

28. The method of 27, wherein the growth takes place at a temperature between about -193 centigrade and about 400 degrees centigrade.

29. The method of claim 27, wherein the growth takes place on the surface of a ultraviolet (UV) transparent material, wherein the energy is delivered through an UV transparent material to the interface of the target material and continues through the product to grow.

30. The method of claim 1, wherein the target material is a petroleum jelly and water/alcohol mixture compressed between wafers with at least one being single crystal sapphire wafers and exposed to UV light.

31. The method of claim 30, wherein the product is single crystal.

32. The method of claim 30, wherein the product is epitaxial.

33. The method of claim 30, wherein the product is doped.

34. A method of material transformation, the method comprises:
providing a target material comprising a metal oxide;
placing the target material within a fluid comprising a hydrogen source; and
applying energy to the target material such that at least some of the target material is transformed to the same material with different bonding configuration containing a dopant.

35. The method of claim 34, wherein the metal oxide comprises one of Aluminum Oxide and Gallium Oxide, or Zinc Oxide.

36. The method of claim 34, wherein a dopant concentration of the material with different bonding configurations is between 0.03% to 0.05% Chromium with lower 0.01% to 0.2% transforms to a dope sapphire.

37. A method for material transformation, the method comprises:
effusing an active ingredient from a reserve-reservoir of atomic hydrogen from within materials that absorb hydrogen gas; and
migrating of target materials to a surface of the reserve-reservoir of atomic hydrogen where the material reacts and transforms to a different configuration.

38. The method of claim 37, wherein the reserve-reservoir of atomic hydrogen is from materials including one of Pd, Nb Au, Ag Zr, Ti, Cu, combinations thereof, and alloys thereof.

39. The method of 37, wherein an instant transformation reaction in part, takes place from between about room temperature and liquid nitrogen temperatures.

40. The method of claim 37, wherein all or in part reaction and transformation with water shows a Ph that is basic.

41. The method of claim 40, wherein a voltage is formed when the activated material is connected as an electrode in pure water with a counter electrode.

42. The method of claim 41, wherein the voltage shows a rate of decay as function of time that corresponds to a diffusion rate of the atomic species in the reserve-reservoir.

43. The method of claim 41, further comprising using a device to measure the diffusion rate of atomic hydrogen, deuterium, or tritium.
